(19) United States
(12) Patent Application Publication
(10) Pub. No.: US 2013/0306139 A1
(43) Pub. Date: Nov. 21, 2013

(54) HYBRID SOLAR SYSTEMS AND METHODS OF MANUFACTURING

(71) Applicant: Paul Alan Bostwick, Oakland, CA (US)

(72) Inventor: Paul Alan Bostwick, Oakland, CA (US)

(21) Appl. No.: 13/953,483

(22) Filed: Jul. 29, 2013

Related U.S. Application Data
(63) Continuation-in-part of application No. 13/461,558, filed on May 1, 2012.
(60) Provisional application No. 61/481,670, filed on May 2, 2011.
(60) Provisional application No. 61/523,147, filed on Aug. 12, 2011.

(51) Int. Cl. H01L 31/058

(52) U.S. Cl. CPC H01L 31/058
USPC 136/248; 136/259

(57) ABSTRACT

A hybrid solar system and method of manufacturing same are described. A solar energy apparatus comprises at least one enveloping tube, at least one heat pipe evaporator, at least one reflector device, at least one reflective filter, and at least one photovoltaic device. The enveloping tube has an outer surface made of transmissive material and an evacuated internal atmosphere. The heat pipe evaporator runs longitudinally within the at least one collector tube. The reflector device is fixedly attached to an inner surface of the enveloping tube such that the reflector device is tilted relative to the normal axis of the enveloping tube, and the reflective filter is located such that light reflecting off the reflector device is directed to the reflective filter. The photovoltaic device is located such that at least a first portion of the light filtered by the reflective filter may be directed to the photovoltaic device and the portion incompatible with the photovoltaic device may be captured within the at least one heat pipe.

### CROSS-REFERENCE TO RELATED APPLICATIONS

This application is a continuation-in-part of and claims priority to U.S. patent application Ser. No. 13/461,558, filed May 1, 2012, which is a non-provisional of and claims priority to U.S. Patent Application Ser. No. 61/481,670, filed May 2, 2011, and U.S. Patent Application Ser. No. 61/523,147, filed Aug. 12, 2011, each of which is hereby incorporated by reference in its entirety.

### FIELD

The present disclosure generally relates to hybrid solar systems for producing combinations of electricity, heat, and optionally transmitting light, from the sun, and methods of manufacturing such apparatus, and to systems and methods of manufacturing apparatus for concentrating sunlight.

### BACKGROUND

Solar energy collection is understood to be desirable as a free energy source. Solar radiation is, however, diffuse (peaking at around just 1300 Watts per square meter) and arrives at ever changing angles and intensities. The collection of this solar energy is further complicated by its heterogeneous and changing mix of light wavelengths. Additionally, solar energy's various alternatives are very inexpensive, energy dense and well established in the market.

When electricity from the sun is desired, the photovoltaic (PV) effect of semiconductors is employed. Economies of scale have made photovoltaic panels containing Silicon cells cost competitive when compared to the most expensive electricity on the market (peak-hour retail watts.) However, solar electric generation is inhibited by the still relatively high cost and low net efficiency (a maximum theoretical of around 25%) of Silicon flat panel collectors. The expense of semiconductor materials and processing is understood to be key a challenge to the economic exploitation of the solar resource for electricity production.

At the high end of the performance efficiency range are multi junction photovoltaic cells that stack a variety of semiconductors, each of which transforms a different range of light-frequencies while allowing the rest to pass through. These multi junction cells are very expensive on a per square meter basis, fortunately they respond well to highly concentrated light (and some claim greater than 40% net efficiency under high concentration.)

At the other end of the expense range are thermal solar collectors that transduce the radiation of the majority of available light frequencies into sensible heat and direct that heat to either storage or immediately to some employment. This efficiency of transformation (greater than 80%) and, relative to photovoltaic conversion, low-cost, are the principal advantages of thermal collectors. The disadvantage for thermal approaches is that they must compete with a variety of inexpensive and energy dense fuel stocks such as natural gas and wood. Further, accomplishing high temperatures (and thus greater energy density and utility) requires more complex mechanisms and attendant higher costs.

Certain market and physical-technical forces have lead to the development of hybrid solar electric/heat systems also known as co-generation or PV-T (for photovoltaic-thermal.) By extracting both electricity and useable heat from a single collector's the net aperture efficiency (energy captured as a percentage of the incoming sunlight) is increased. A common scheme is to mount the photovoltaic cells to a circulating coolant channel and drive the coolant through that channel to maintain a lower than otherwise accomplished temperature for the photovoltaic material. This increases the voltage and thus the watt-hour output. Additionally the harvested heat can be directed to some useful function. Heat is usually of lower economic value (watt-hour for watt-hour) so a higher electrical output is usually preferred, all other things being equal.

Known PV-T (or “hybrid collector systems”) can be usefully grouped into concentrating and flat plate collectors. The practice of allowing the radiation to enter the photovoltaic material full-spectrum and only afterward to remove the surplus, untransformed fraction of energy as heat is the same in both groups of collectors. Alternatively, it has been suggested that splitting the spectrum into diverse streams for exploitation by physically separate photovoltaic cells or uses would allow for somewhat less expensive (single or tandem junction) photovoltaic targets to be used. This would also reduce the need to scrub unconvertible energy. A key goal of these approaches is lowering the operating temperature for the photovoltaic components. The difficulty encountered here is the law of diminishing returns and each sub-assembly or surface employed brings with it production costs and energy losses. In addition the multi-junction cells remain expensive and so require high concentration collectors to be economically viable. In known high concentration collectors there is a concomitant waste of indirect light and a demand for greater heat management and more sophisticated sun tracking.

It is known that optical concentrator designers must choose between the higher maximum concentration ratios available to narrowly focused tracking systems (and in the process loosing the varied but considerable fraction of light that is not approximately collimated in the direct normal path from the sun's disk) or skipping the expense of tracking and trading maximized concentration for relative thrift in assembly and installation. The former are generally Cassegrain and Fresnel based concentrating collectors while the latter employ non-imaging optics often of the sort pioneered by Roland Winston and discussed in his book “Non Imaging Optics.”

There remains a need for maximized solar collection over a broad range of light conditions in an inexpensive device suitable for rooftop mounting. More particularly, there is a need for a solar collection apparatus that provides both high temperature heat relative to the ambient temperature and electricity. At the same time a low temperature work environment is desirable for the photovoltaic components of solar collection apparatuses. There is also a need for a hybrid PV-T system in which energy fractions that cannot be collected by photovoltaic means can be scavenged as heat and/or exhausted as inexpensively and decisively as possible so that it and the sun do not excessively magnify to the cooling load of the building below or degrade the performance of the photovoltaic components. Additionally there is a need for a hybrid solar collection system that can provide a variety of energy and service streams from the same system variously compatible with a building's energy needs and to reduce conversion losses.

### SUMMARY

Embodiments of the present disclosure alleviate to a great extent the disadvantages of known systems by providing solar energy collection systems and methods capable of delivering thermal and/or electric power. In certain embodiments, the system may also deliver light filtered of infrared and ultraviolet (UV) and so desirable for lighting. More particularly, disclosed embodiments provide hybrid PV-T systems and methods wherein a fraction of light is transformed to sensible heat and conducted through a heat pipe for solar thermal power in tandem with at least one photovoltaic cell generating PV energy. Exemplary systems and methods include evacuated collector tubes with mixed outputs of DC voltage, heat, usable light, or combinations of all three and the provision of comprehensive shade. Exemplary embodiments contain within an evacuated tube, a light path including a band pass filter that reflects, preferentially, the light useful for a given photovoltaic cell and passes the majority of the remainder into a heat pipe. The tube provides a structure and protection for the optics. Due to the evacuated atmosphere, the tube also suppresses convection and conductive losses of the collected heat from the heat pipe.

Sunlight incident on the earth's surface may be usefully divided into direct normal irradiance (DNI) and non-direct irradiance (or scatter or skylight.) Exemplary apparatus maintain different interwoven paths for these two energy streams. It is an object of this appliance, device and method to selectively and comprehensively employ the light of both types in an economically advantageous way. Consider DNI first. The disclosed optical elements separate the energy in the DNI into one path for the photovoltaic and second scavenging heat path. The light directed to the photovoltaic cell may be filtered and/or concentrated by a Cassegrain style system. The photovoltaic cell may, in this way, receive and convert more light energy per square area with less performance-sapping heating that would otherwise be caused by absorbing unusable wavelengths filtered by the band pass wavelength filter. The modularity of the disclosed device permits the design of installations to provide, not only differing mixes of process quality heat and electricity, but also filtered light for day lighting use.

The light that is directed away from the photovoltaic cell is primarily the light of an inappropriate wavelength for the cell species or light that arrived at an angle of incidence that is incompatible with the concentrating optics. This light energy would, in other known hybrid collectors be absorbed by the photovoltaic cell (raising its temperature unnecessarily) and/or the attendant system. Alternately, in some known art, this energy is allowed to exit the back of the collector. Exemplary embodiments of the disclosed apparatus and device instead work to capture the majority of the diffuse as well as the light of incompatible wavelengths within its heat circuit.

Exemplary embodiments contain a scatter collection fin bonded to a heat pipe within the evacuated tube. Together the fin and heat pipe may be coated with a broadly absorptive and minimally radiative surface (a “selective coating”) to absorb energy into the heat pipe. From there it is conducted to the condenser at the high end of the evacuated tube.

Now consider the paths of the scatter (non-direct normal light.) The heat circuit components act as the primary and secondary destination for diffuse light. The majority of scatter (or light energy from outside the disk of the sun) will either transmit into the fin and or heat pipe in the majority, or it will reflect out of the tube skyward in the minority. The other fraction of light directed to the heat circuit is that fraction of the direct normal irradiance (DNI) that was of an incorrect wavelength for the photovoltaic cell (and so unable to drive the photovoltaic effect.) That otherwise unusable fraction of the light is passed, instead, to the heat pipe, scatter fin and a light-spill capture cap. The fin is also well positioned to catch light misdirected by imperfections in the various surfaces and materials of the device.

The frequency splitting is accomplished here in an interlaced fashion that provides high net efficiency (thermal watts and electric watts taken together) without the usual sacrificing of electric output. Because the photovoltaic cell's location is in just one of the focal points of the filter assembly, it may be separate and thermally isolated from the heat pipe and scatter fin locations. Thus the heat pipe and scatter fin can, with minimal warming of the photovoltaic cell, achieve higher and more useful working temperatures without degrading the apparatuses electrical performance.

In exemplary embodiments, a solar energy apparatus (or collector tube) comprises at least one enveloping tube, at least one heat pipe evaporator, at least one reflector device, at least one reflective filter, and at least one photovoltaic device or a UV filter. The outer surface of the enveloping tube is made of transmissive material and an evacuated internal atmosphere. The heat pipe evaporator runs longitudinally within the at least one enveloping tube. The reflector device is fixedly attached to an inner surface of the enveloping tube such that the reflector device is tilted relative to the normal axis of the enveloping tube, and the reflective filter is located such that light meeting the reflector device is directed to the reflective filter. In exemplary embodiments, the reflector device is tilted at an angle of about 38-39°. In exemplary embodiments, the reflector device is tilted such that a focal point and vertex is at least 38° 26′ 21″. The reflector device may comprise a reflective coating. The photovoltaic device is located such that at least a first portion of the light filtered by the reflective filter is directed to the photovoltaic device. The first portion of light may comprise direct normal light. In exemplary embodiments, the photovoltaic device and the reflective filter are located such that the photovoltaic device is shaded from direct (normal) light by the reflective filter. A second portion of the light is transformed to sensible heat by, and conducted through, the heat pipe evaporator. The second portion of light may comprise direct normal light and indirect light incident upon the heat pipe evaporator. A third portion of light may comprise the indirect light (and a minority of the direct light) reflecting off the reflector device to a scatter fin such that this light is absorbed by the heat pipe evaporator or exits the solar energy apparatus.

In exemplary embodiments, the solar energy apparatus (or “collector tube”) further comprises a condenser fluidly connected to the heat pipe evaporator. The sensible heat may be conducted through the heat pipe evaporator to the condenser. The solar energy apparatus may further comprise at least one scatter fin fixedly attached to the at least one heat pipe evaporator.

In exemplary embodiments, the light entering the solar energy apparatus is usefully broken into a plurality of paths, and the light collected (and otherwise managed) includes direct normal light and indirect light. The direct normal light and the indirect light may be concentrated at different ratios. As a consequence of the design's virtues, different concentration ratios can also be obtained for selected and deselected wavelengths. One such path may comprise a fraction of the direct normal light passing through a reflective filter to a heat pipe evaporator and/or a light-spill capture cap.

An exemplary solar energy apparatus comprises at least one enveloping tube having an outer surface made of transmissive material and an evacuated internal atmosphere, at least one heat pipe evaporator running longitudinally within the at least one enveloping tube, at least one reflector device fixedly attached to an inner surface of the enveloping tube such that the reflector device is tilted relative to the normal axis of the enveloping tube, at least one reflective filter located such that light reflecting off the reflector device is directed to the reflective filter, and at least one location within the enveloping where a photovoltaic device or a UV filter may be located such that at least a first portion of the light filtered through the reflective filter is directed to the photovoltaic device or through the UV filter. A second portion of the light is transformed to sensible heat and conducted through the heat pipe evaporator. In exemplary embodiments, the reflector device is tilted at an angle of about 38-39°.

Now consider an exemplary array that may be constructed with the disclosed apparatus. Exemplary embodiments of a solar energy system (or “hybrid solar system or array”) comprise a plurality of enveloping tubes and a support assembly holding the plurality of collector tubes. Each enveloping tube comprises at least one heat pipe evaporator, at least one reflector device, at least one reflective filter, and at least one photovoltaic device. The enveloping tube has an outer surface made of transmissive material and an evacuated internal atmosphere. The heat pipe evaporator runs longitudinally within the at least one enveloping tube. The reflector device is fixedly attached to an inner surface of the enveloping tube such that the reflector device is tilted relative to the normal axis of the enveloping tube, and the reflective filter is located such that light reflecting off the reflector device is directed to the reflective filter. The reflector device may comprise a reflective coating. The photovoltaic device is located such that at least a first portion of the light filtered by the reflective filter is directed to the photovoltaic device. In exemplary embodiments, the photovoltaic device and the reflective filter are located such that the photovoltaic device is shaded from direct light by the reflective filter. A second portion of the light is transformed to sensible heat and conducted through the heat pipe evaporator.

Exemplary solar energy systems may further comprise a heat exchanger housing connected to the support assembly. Exemplary solar energy systems may further comprise a tracking system connected to the support assembly. The tracking system may comprise a drive assembly operatively connected to the support assembly to rotate the plurality of collector tubes. In exemplary embodiments, the support assembly holds the plurality of collector tubes in at least two substantially parallel ranks such that the collector tubes held in a first rank (or “plane of collector tubes”) partially shade the collector tubes held in a second rank of tubes positioned at the centers of the spaces between the collector tubes in the first or foremost rank. In exemplary embodiments the supporting assembly of the solar energy system maintains a front rank and a hind rank of collector such that more than 97 percent of light is prevented from passing through. The majority of light incident upon the system is transformed to sensible heat and conducted through the heat pipe evaporator and a select fraction of the direct normal light incident upon the collector is employed for lighting or electrical generation via photovoltaic transformation and an unused fraction of the light is directed up and out of the collection system and back to the sky.

It is another aspect of the present disclosure to provide methods of manufacture for solar systems. Exemplary embodiments further include methods of generating solar thermal energy and solar photovoltaic energy comprising providing at least one enveloping tube, providing at least one reflector device, at least one reflective filter, at least one photovoltaic device, and at least one heat pipe evaporator. The enveloping tube is provided with an outer surface made of transmissive material and an evacuated internal atmosphere. The reflector device is fixedly attached to an inner surface of the enveloping tube such that the reflector device is tilted relative to the normal axis of the enveloping tube, and the reflective filter is configured such that light reflecting off the reflector device is directed to the reflective filter. The photovoltaic device is configured such that at least a first portion of the light filtered through the reflective filter is directed to the photovoltaic device. The heat pipe evaporator is configured such that it runs longitudinally within the at least one enveloping tube and such that a second portion of the light is transformed to sensible heat and conducted through the heat pipe evaporator. Exemplary methods further comprise fixedly attaching at least one scatter fin to the at least one heat pipe evaporator. Exemplary methods further disclose strategies for using high speed bottle making equipment to generate reflectors, to use “as built” topography and “as built” data about glass or other parts to make more perfect apparatuses of less perfect parts from less perfect manufacturing facilities.

Exemplary methods further comprise directing the light entering the enveloping tube such that the light is broken into a plurality of paths. The light may include direct normal light and indirect light, and the direct normal light and the indirect light may be concentrated at different ratios. In exemplary methods, the first portion of light begins as direct normal light and traces of indirect light and ends at a photovoltaic device or an exit for useful, heat and UV-scrubbed, light. The second portion of light may comprise direct normal light and indirect light incident upon, and absorbed by, a heat pipe evaporator. A third portion of light may comprise indirect light and traces of direct normal light reflected off the reflector device to a scatter fin, heat pipe evaporator and light spill capture cap (or directly incident upon the scatter fin) such that this indirect light and traces of direct light enters the scatter fin, capture cap and heat pipe evaporator, or exits the enveloping tube.

Accordingly, it is seen that systems, apparatuses for and methods of generating solar thermal and photovoltaic energy are disclosed. The disclosed systems, apparatuses and methods provide both high temperature heat relative to the ambient temperature, and a low temperature work environment for the photovoltaic components. These and other features and advantages will be appreciated from review of the following detailed description, along with the accompanying figures in which like reference numbers refer to like parts throughout.

### BRIEF DESCRIPTION OF THE DRAWINGS

These features together with the various ancillary provisions and features which will become apparent to those skilled in the art from the following detailed description, are attained by the system and method of manufacturing of the present disclosure, preferred embodiments thereof being shown with reference to the accompanying drawings, by way of example only, wherein:

FIG. 1 illustrates a perspective view of an exemplary embodiment of a hybrid solar energy system in accordance with the present disclosure;

FIG. 2 is a sectional view 2 & 3-2 & 3 of the hybrid solar energy system of FIG. 1;

FIG. 3 is a sectional view 2 & 3-2 & 3 of the hybrid solar energy system of FIG. 1;

FIG. 4 is a sectional view of an exemplary embodiment of a hybrid solar energy system in accordance with the present disclosure;

FIG. 5 is a sectional view of an exemplary embodiment of a hybrid solar energy system in accordance with the present disclosure;

FIG. 6 is a longitudinal sectional view 6-6 of the hybrid solar energy apparatus of FIG. 1;

FIG. 7 is a sectional view of 7-7 of the solar energy apparatus of FIG. 6;

FIG. 8 is a sectional view of one half of a solar energy apparatus in accordance with the present disclosure with representative light rays;

FIG. 9 is a sectional view of one half of a solar energy apparatus in accordance with the present disclosure with representative light rays;

FIG. 10 is sectional views of alternative embodiments of solar energy apparatuses in accordance with the present disclosure;

FIG. 11 is a perspective view of an exemplary embodiment of a bottle preform for a solar reflector in accordance with the present disclosure;

FIG. 12 is a side cross-section view of 12-12 of the bottle preform of FIG. 11;

FIG. 13 is a top cross-section view of 13-13 of the bottle preform of FIG. 11;

FIG. 14 shows a side view of a heat circuit in accordance with the present disclosure;

FIG. 15 shows a side cross-section view of a solar energy apparatus sub-assembly in accordance with the present disclosure;

FIG. 16 shows a cross-section view of 16-16 of the solar energy apparatus of FIG. 15; and

FIG. 17 is a process flow diagram of an exemplary solar energy apparatus manufacturing method in accordance with the present disclosure.

FIG. 18 is a cross-section schematic of an an exemplary alternative embodiment to FIG. 6 of a solar energy apparatus, representing a “Kuttner” Cassegrain reflector format and showing a biased aim, not normal to the enveloping tube wall and coating on inside of tube ghosted for clarity.

FIG. 19 is an isometric view of an exemplary alternative embodiment to FIG. 6 representing a heat pipe evaporator behind the reflectors and the band pass reflective filter mounted on an adjacent reflector's wall as well as reflectors without symmetry on the long axis.

FIG. 20 is a general arrangement of an exemplary embodiment of a hybrid solar energy apparatus with a heat pipe evaporator behind the reflectors and an extreme bias in the Cassegrain reflector with sections marked for FIG. 21, FIG. 22 and FIG. 23.

FIG. 21 is a cross-section of an exemplary embodiment of a hybrid solar energy apparatus with a heat pipe evaporator behind the reflectors and an extreme bias in the Cassegrain reflector from FIG. 20.

FIG. 22 is a transverse-section of an exemplary embodiment of a hybrid solar energy apparatus with a heat pipe evaporator behind the reflectors and an extreme bias in the Cassegrain reflector from FIG. 20.

FIG. 23 is a plan view of an exemplary embodiment of a hybrid solar energy apparatus with a heat pipe evaporator behind the reflectors and an extreme bias in the Cassegrain reflector from FIG. 20

Reference numbers are used in the Figures to indicate certain components, aspects or features shown therein, with reference symbols common to more than one Figure indicating like components, aspects or features shown therein.

### DETAILED DESCRIPTION

In the following paragraphs, embodiments will be described in detail by way of example with reference to the accompanying drawings, which are not drawn to scale, and the illustrated components are not necessarily drawn proportionately to one another. Throughout this description, the embodiments and examples shown should be considered as exemplars, rather than as limitations of the present disclosure. As used herein, the “present disclosure” refers to any one of the embodiments described herein, and any equivalents. Furthermore, reference to various aspects of the disclosure throughout this document does not mean that all claimed embodiments or methods must include the referenced aspects.

Generally, disclosed embodiments include concentrating, tracking, hybrid evacuated tube solar energy apparatus (or collector tubes) 1 and solar energy systems 110. A plurality of evacuated collector tubes 1 may be held in an assembly comprising a solar energy system 110 and inclined to match the sun's 200 elevation. Each collector tube 1 of the solar energy system 110 can be rotated on a long axis to aim its internally arrayed concentrating elements 11. Disclosed embodiments of a collector tube (or apparatus) 1 has, as outputs, a configurable mix of: voltage, heat, usable light and comprehensive shade service. Also disclosed herein are methods of construction and assembly for solar energy apparatuses and systems thereof. A linear array of Cassegrain subunits 11 may be incorporated within the collector tubes 1. Their form factor is elaborated below.

These Cassegrain subunits 11 and the method of assembly provide for a configurable product-line with flexibility in specification to conform to the capabilities and resources of a manufacturer. Moreover, the novel mix of high-temperature heat and modular concentrators allows a system to be tailored to meet a variety of energy and service production needs—all within a single solar energy system 110 employing variously appointed collector tubes 1. Electricity, process heat, domestic hot water, air conditioning, refrigeration, space heating, shade and heatless light may all be powered and/or supplied from the same solar energy system 110.

The solar collection area (or aperture) of each solar energy system 110 may be occupied by a plurality of collector tubes (or apparatuses) 1 held in a pair of parallel planes 7 and 8; one foremost rank 7, closer to the sun than the other, hindmost, rank 8. The collector tubes 1 may be spaced such that when the sun is at the peak of its travel, each of the tubes in the first rank or plane (i.e. closest to the sun) captures a full exposure of the sunlight and skylight. The farthest, or hind most rank (or plane) of tubes, is partially shaded by the foremost rank so that they may catch edge reflections from the first rank and positively complete the occupation of the gaps in the aperture provided by the first rank's spacing. The overlap compensates for the relatively high reflection losses along the flanks (or outer edges) of the foremost rank 7 of collector tubes 1. By catching the edge reflections from the first rank 7 in their heat circuits 21 and preventing the edge reflections from passing through to the structure beneath, the solar energy system 110 provides comprehensive shade. The degree of overlap (east west spacing amongst each rank) is an exercise in value engineering where the cost of each specified collector tube apparatus 1 (a function of how many and which energy streams are desired) is set against the projected market value of those energy streams (and services.) Closer spacing of the tubes generally favors mid-day energy capture and electrical production as it shades to a greater degree the less productive hind most rank.

The foremost 7 and hindmost 8 ranks of collector tubes 1 may be sufficiently far apart in the sunward dimension that air can circulate, as can installation tools and installer's hands. The two layer approach maximizes the use of the available solar aperture for a given installation site. It also prevents “leakage” of sun through the solar energy system to heat the roof of the building below thereby preempting a cooling load. The air circulation gaps also reduce the wind load generated by the collector area and improve cooling of the rear heat sinks 43 via buoyant airflow. The collector tubes 1 thus work individually and as a group, to form a maximally reflective and obstructive layer for solar radiation. With this stacked arrangement they perform as a comprehensively obstructive and reflective, “cool roof.” This effect is known to significantly reduce the cooling load at the peak of the air conditioning load period of the day. Maximization of aperture use is another function of this arrangement.

Enclosed in each collector tube 1, and interlaced with the Cassegrain optical elements 11 may be a heat pipe evaporator (s) 45 and scatter absorbing fin(s) 46. The parts of the light spectrum incident on the collector tube 1 that are either not transformable by the chosen photovoltaic material, or arrive at angles incompatible with the Cassegrain reflectors 11, or undesired in the exit for filtered light 74, are either absorbed by the heat pipe evaporator 45 and its scatter fin(s) 46 in the majority or reflected back skyward 300 in the minority.

This wavelength selection and segregation is accomplished by the secondary element in the Cassegrain subassembly 11: a band pass reflective filter 41 (or “cold mirror”). Photovoltaic devices, or cells 38, sit at one of the focal points of the band pass reflective filters and are lit thereby with light selected for proper wavelength compatibility with them.

Light wavelengths not transformable by the chosen photovoltaic cells 38 are directed away from the photovoltaic cells 38. Due to the specificity of the light incident upon them, the photovoltaic cells 38 may operate at lower temperatures for a given light flux and thus work more efficiently.

Because the collector tubes 1 house concentrating optics and those optical elements disclosed here require tracking of the sun's 200 progress throughout the day, the collector tubes 1 are held in a support assembly 2, a rack with a tube-drive and heat exchanger interface 112 that provides for automated extending of the elevation legs 5. This extension and contraction tips the entirety of the two planes 7 and 8 of the solar energy system 110 up and down together to correspond to the seasonal changes in the elevation of the sun's path. The place of the sun along that path (east-west) as each day progresses is tracked by rotating each tube on its central axis. At the end of the collection day the collector tubes 1 are counter rotated to an eastward facing focus to be ready for the next day's collection. Likewise, azimuth is tuned via adjustment of elevation legs 5 in anticipation of the next day's solar path. The software control of the movement provides also for modulating the collection of energy by intentionally miss-tracking the sun and thereby allows for “off” and “heat only” tracking patterns and positions: these options are useful for installation, service, safety and energy production management.

In exemplary embodiments of the solar apparatus (or collector tube) the enveloping tube 39 is the first point of contact with incoming light. This is true of the two sources of light, the direct normal irradiation (“DNI”) 9 and the indirect light (or “scatter”) 10 that is understood to be light coming from all directions excluding the DNI. All light paths therefore start at the sun 200 or the dome of reflective materials surrounding the collector tube exclusive of the disk occupied by the sun (the “sky”) 300. These two starting sources have several, functionally grouped, end destinations after they encounter the enveloping tubes 39 of the arrayed collector apparatuses 1 of the solar collector device 110: these end destinations are, the filtered light exit 74 and so employment in a photovoltaic device 38 or transmission through a filter 81 and the scatter fin 46, the heat pipe evaporator 45 and the light-spill capture cap 51 (46, 45 and 51, via thermal bonds conduct to a common point and so are functionally one), also, an exit back to the sky 300 as scatter 10 or to the sun 200 also as scatter 10 (both of which, in this instance, are functionally the same for the apparatus) and finally absorption by the apparatus (to be lost to convection via buoyant air flow.)

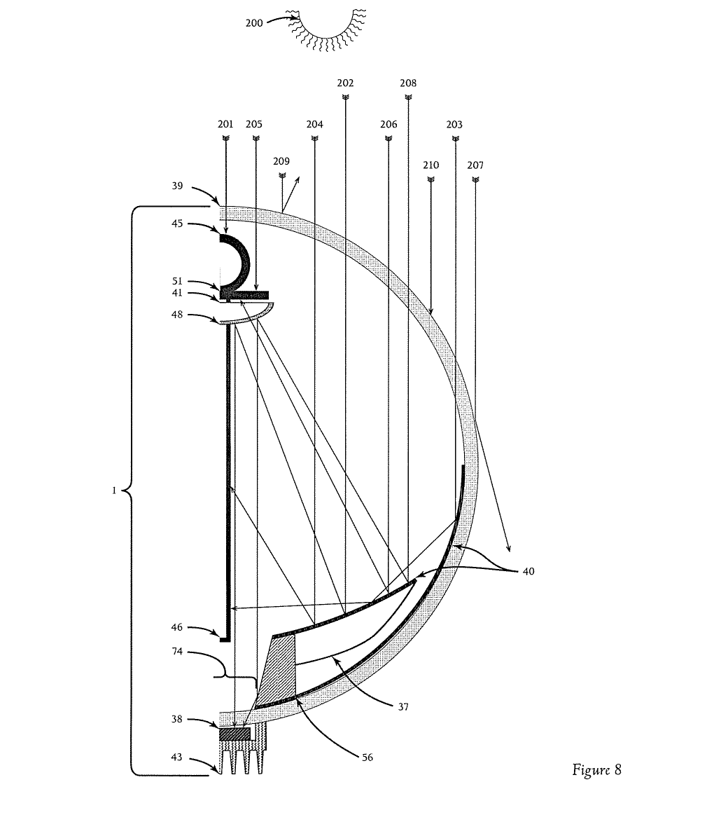

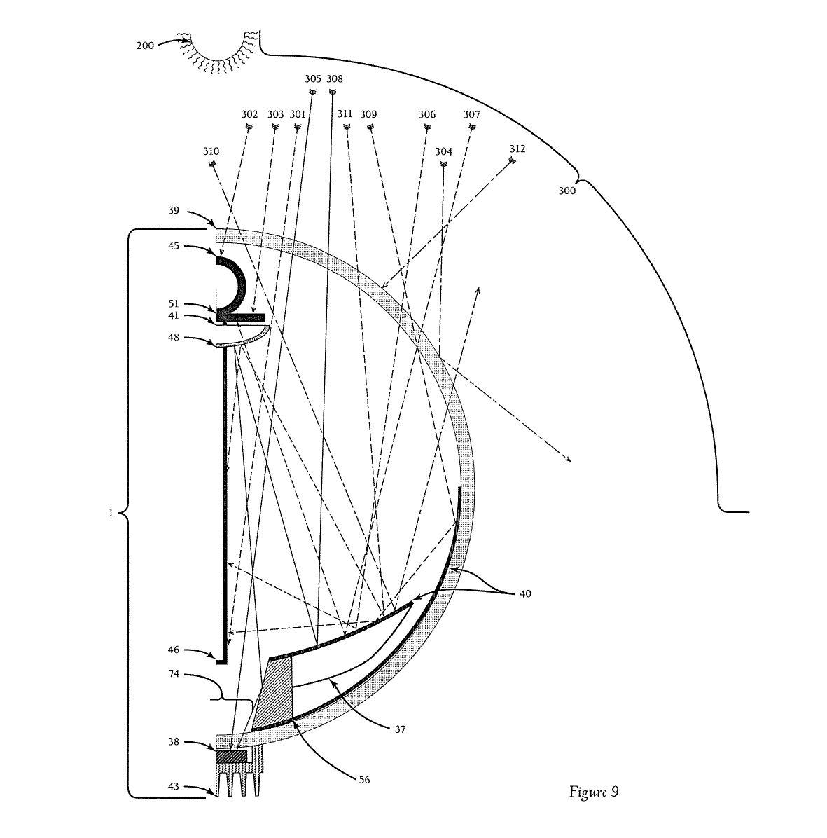

In FIGS. 8 and 9 the particulars of these paths connecting the sun's 200 light (DNI) 9 and the sky's 300 light (scatter) 10 to and through the apparatus's elements in various sequences (each with an exemplary numbered path) to the principal end destinations are shown. These paths are illustrated as 201, 202, 203, 204, 205, 206, 207, 208, 209, 210 in the case of the DNI 9 and 301, 302, 303, 304, 305, 306, 307, 308, 309, 310, 311 and 312 in the case of scatter 10.

Among the rays 201-210, of primary value and of maximized flux in exemplary embodiments of the apparatus, are the paths 202 and 208 which deliver light to the band pass reflective filter 48 and are, principally, just the selected wavelengths 49 for transmission to the exit for filtered light 74. These (202 and 208) combined with ray paths 305 and 308, form a first portion of light. Forming a second portion of light, amongst the rays 201-210 and 301-312 are those that end immediately in the exposed surface of the heat pipe evaporator 45. They are 302 and 201 and contribute immediately to the heat circuit 21. The third portion may either be absorbed by the scatter fin 46 or exit the apparatus 1. This third portion's paths are numbered 203, 204, 205, 206, 207, and 209 and also ray paths of the indirect light numbered 301, 303, 304, 306, 307, 309, 310 and 311. Of the third portion, paths 207, 209, 304, and 310 are the exiting paths. The remaining rays (not comprised by the portions above) are those small fractions absorbed by the apparatus represented by rays 210 and 312.

The comprehensive majority formed by the first, second and third portions of light, provides that light of all sources and paths are minimally admitted past each apparatus 1 and, moreover by the overall hybrid solar device 110 due to the relative arrangement of (and internal composition of) the collector tubes 1. The light rays 201-210 and 301-312 (which stand for the plurality of paths through and around the collector tubes 1) are comprehensively and to a high degree, employed by the apparatus and device. The rays not in the first three portions are 210 and 312.

Amongst the sky 300 sourced scatter 10 the rays are illustrated as 301-312 and of particular interest for this light are the rays that terminate in the heat circuit 21. This is, by design, the majority of the incoming indirect light 10. Rays 301, 302, 303, 304 (304 as a result of becoming part of the indirect incoming light 10 for an adjacent collector tube 1 in the hind rank) 306, 307, 308 (in part) and 309 represent the paths taken by the large majority of the indirect incoming light 10 incident on the collector tube 1 of the area comprising a hybrid solar collector. They are concentrated both geometrically (the area of the exposed heat circuit components 45, 51, 46 is smaller than the aperture area of the enveloping tube 39) and, moreover, as sensible heat in an evacuated atmosphere 42. This sensible heat can buildup (as elevated temperatures) to concentrate energy over time. In addition, the temperature at which the working media of the heat pipe evaporator 47 condenses at the heat pipe condenser 16 may be manipulated at the design stage (giving a further, largely independent degree of freedom in planning thermal concentration). Of less interest, and in exemplary designs may be minimized, is the naturally small fraction that is represented by 305 (which degrades slightly the performance of the components placed in the exit for filtered light 74) and the other likewise small fraction represented by 310, which is reflected out of the apparatus 1. Some of this reflected out light meets adjacent collector tubes 1 and is treated as another instance of incoming indirect irradiance 10 for that tube, the rest of it, leaves skyward 300.

Exemplary embodiments are optimized for the paths (202 and 208) that direct DNI 9 into the exit for filtered light 74 via the band pass reflective filter 41 and second for the paths that end in the heat circuit 21. The “reflective path” from the secondary elements (or band pass reflective filters) 41 reflects the desired (usable by the selected photovoltaic cell 38) fraction of the light 49 to a small target area 74 (also known as the exit for filtered light). From there it is used in either: heatless light collection (for illumination for example) or to energize photovoltaic material 38 for the generation of DC voltage. The size and shapes of the primary reflectors 37 and secondary optical elements (reflective filter) 41 represent two of many points of design freedom within the solar energy apparatus (collector tube) 1 and can be variously composed to place the focal point above, at or below the surface of the primary reflector 37 and to, via conventional design methods for Cassegrain optic systems, pick a sunlight multiple, appropriate to the selected photovoltaic material, photovoltaic cell 38 design, or lighting strategy. Furthermore, known Cassegrain optic design theory and methods can guide the articulation of the relative sizes of the first second and third portions of light to achieve product performance goals to a close degree.

In an exemplary embodiment without daylighting options employed, and composed according to Cassegrain optic design theory but without efforts to optimize the division of the three portions of light, was by virtue of the form factor described above and below, able to employ, absorb or reject back to the sky, all but 2% of the incident light of all types.

The row of primary reflector devices 37 may be held in a single line to act as either a trough, or as a series of wells. In the case of the trough the secondary element (band pass filter 41) can be the surface of the bottom of the heat pipe evaporator 45 or a separate component as in the Cassegrain embodiments illustrated here. In the case of the row of shallow wells or bowls, the secondary 41 may be held above the target area by a mount 44.

The heat pipe evaporator 45 and scatter fin 46 may be bonded thermally and coated all around with a broad-spectrum absorptive coating 48. The scatter fin 46 extends down into the primary reflector wells or trough and directly away from the sun. This scatter fin 46 provides for both stiffness in the heat pipe evaporator 45 and for the collection of scatter 10 and the suppression of stray specular reflection to the ground of sky images or the like, a significant advantage over a simple compound reflector system without it. The fin 46 also allows the heat pipe to be narrower in cross section east west and so permits in some embodiments more light of the DNI 9 to pass and hit the primary reflective device 37. The heat pipe evaporator 45 and fin 46 can, optionally, use coatings 48 that are less than optimally absorptive and instead be coated with an emphasis on the aesthetic performance of the collectors at minimal cost to overall performance and no impact on electrical performance.

Each of the Cassegrain subassemblies 11 can be made with varying degrees of precision depending on the desired price or performance point for the product. Parabolas are desirable but spherical sections and other non-parabolic sections can work to a degree given the non-imaging aspect of the scheme and are generally less expensive to accomplish. The light reflected from the primary reflective devices 37 needs to be convergent at the diameter of the secondary reflective filter device 41, which can be designed to “correct” the primary's light pattern as it redirects the light to the exit for filtered light 74. Additional errors may be managed via a collimating/homogenizing tube 56 at the base of the primary mirror. Again this is a value engineering exercise to balance PV costs, concentration ratios and heat values against manufacturing costs and price point goals.

Usually the exit for filtered light area 74 is in the bottom center of the primary (as in traditional Cassegrain Telescopes with a rear exit), but this is not a requirement. For situations where the solar energy system array 110 will be mounted in geographic locations with very low or very high latitudes the Cassegrain modules 11 can (at the time of manufacture) be canted toward the foot of the array or toward the header of the array to create a tilting bias for the tubes and for the resulting assembly. In very low latitudes a bias toward the header would allow the heat pipe evaporator 45 to work properly since the heat pipe's condenser end 16 works better when elevated above the evaporator segment 45. The trade-off here is a slightly less efficient coverage of the available aperture in exchange for the proper functioning of the heat-pipe's fluidly connected evaporator 45 and condenser 16 ends. Some higher latitude installations could benefit from a bias toward the base, as this would allow for the assembly to lay closer to a roof for instance. Aesthetic and other logistical limitations on sensitive sites are also addressed with these sorts of biased collector tubes 1.

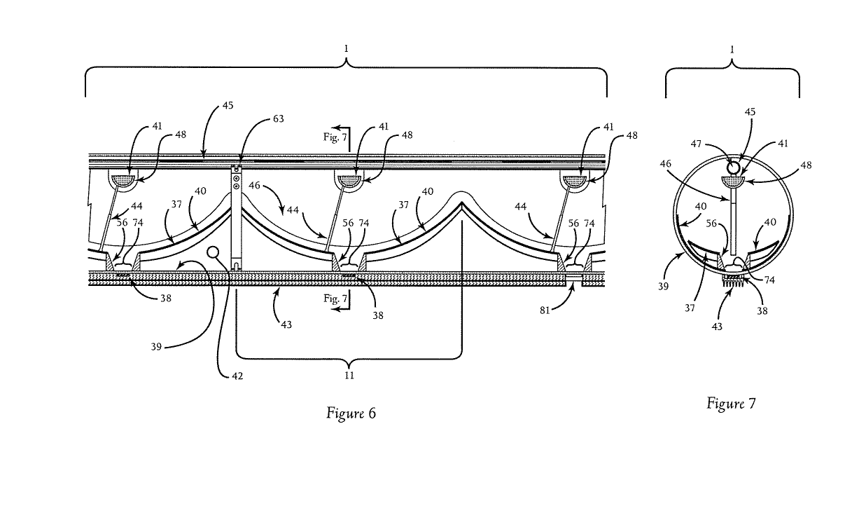

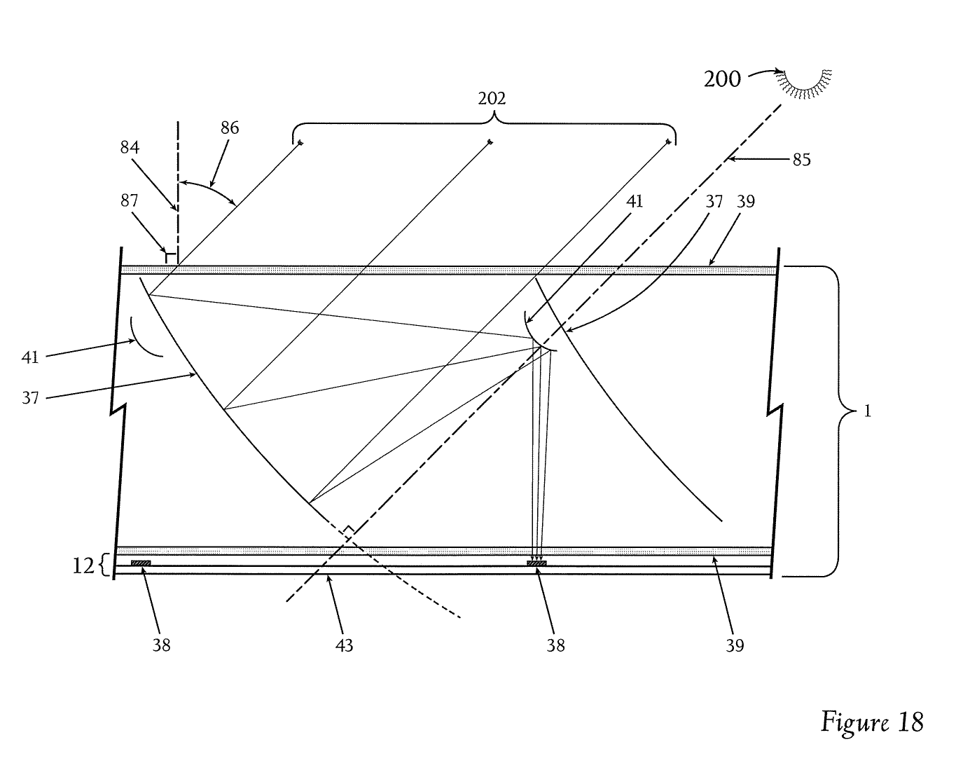

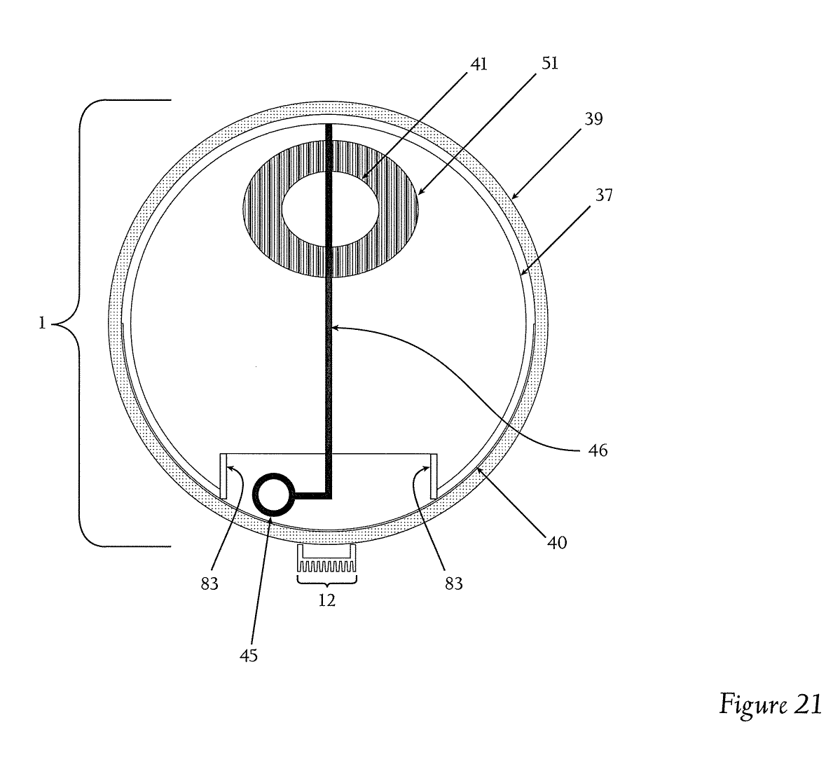

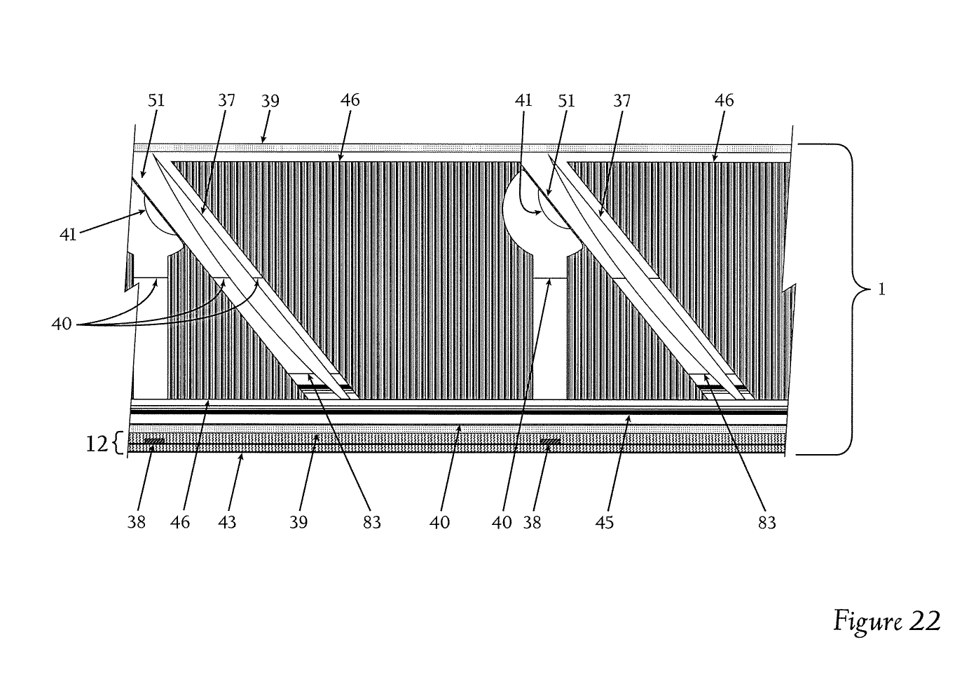

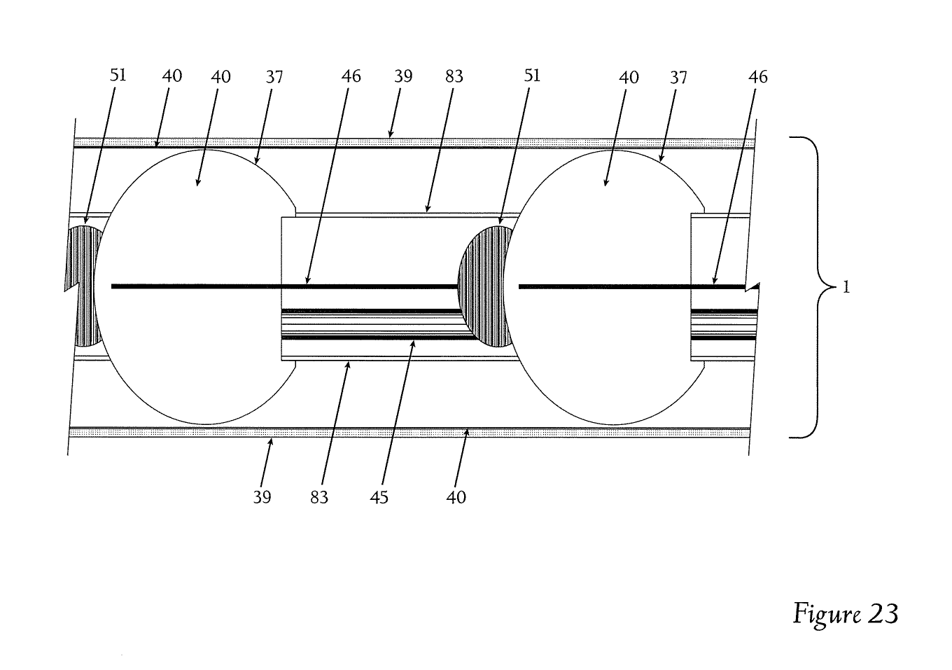

Solar tracking must address the two axis of perceived solar movement. Elevation (height over the horizon) and Azimuth (East West travel) vary over the course of a day and each day of the year has a subtly different apparent path due to the tilt of the Earth's axis relative to the ecliptic and the eccentricity of the earth's orbit. Calculating that path as seen from a given location and time on earth is known art. Articulation of Cassegrain optical devices as a whole to keep in time with that apparent path is also known art. Furthermore impinging upon the design are the requirements of installations at tropics and between the tropics (and especially at the equator.) Such equatorial installations have the additional condition of a solar path that is, in the summer season, more than 23° beyond the zenith (directly over head.) Simple contraction of the elevator adjustment legs 5 to keep an unbiased collector tube 1, such as that in FIG. 6, perpendicular to the DNI 9 (light straight from from the disk of the sun) would place the heat pipe condensers 16 well below the heat pipe evaporators 45 (and defeat their function.) The disclosed apparatus 1 addresses this by building into the reflectors 37 a compensating tilt (or bias) angle 86 relative to the enveloping tube's normal 84. FIG. 18 and FIG. 20-23 elaborate on bias in the aim of the reflectors 37 and their associated bandpass reflective filter 41 and their associated aiming line 85.

The acute angle (bias) 86, is shown in FIGS. 18 and 20-23. This allows the enclosed heat pipe elements 45 and 16 to exploit gravity for the return of the condensed heat pipe working media 47 to the sun-exposed evaporating segment of the heat pipe (evaporator) 45 even at the extremes of sun elevation experienced at the earth's equator. The combination of the angle required for condensate return and the beyond-zenith elevation of the sun at equatorial locations is derived here: 15° (for the condensate return) plus 23° 26′ 21″ (the maximum beyond zenith)—a sum of 38° 26′ 21″. Within the Enveloping Tube 39, the acute angle to the sun is compensated for by Cassegrain sub-units 11 formed and mounted such that the focal point and the vertex of each Reflector 37 (the aiming-line 85 being the line passing through the focal point of the reflector 37, the vertex of same and the center of the Sun 200.) is at least 38° 26′ 21″. This permits the Cassegrain sub-unit 11 to be aligned 85 with the Direct Normal Irradiance 9 of the Sun 200 when the Sun 200 is at its greatest annual elevation without tipping the enveloping tube 39 beyond a functioning angle for the enclosed heat pipe evaporator 45 and condenser 16. A 39° bias 86 (rounded up for convenience) from normal to the enveloping tube wall)(90°) (marked as dashed line 84) amounts to 51° between the collector tube's 1 long-axis and the aiming-line of the Cassegrain sub-unit 11. This is the maximum bias required for an equatorial installation (which would experience the most challenging range of sun positions relative to the Zenith.) The biasing of the internal Cassegrain sub-units 11 does employ more collector material overall for a given aperture—so tubes with less bias than the maximum would be desirable for the tropics and above. A 15° from normal head-ward bias 86 would suffice at tropical elevations (where, by definition the sun has, at the most, 90° of elevation.) Further, above and below the tropical elevations, as discussed above, the bias can be away from the tube-drive and heat exchanger interface 112 (foot-ward) to keep the array from being too “upright”—creating aesthetic concerns or shading problems from multiple rows of hybrid solar energy systems 110. The foot-ward, neutral and head-ward bias 86 permutations discussed and illustrated here are conceived and illustrated as permanent biases 86, introduced at the time of design and manufacture. It is conceptually possible for the reflector 37 and band pass reflective filters 41 to articulate within the enveloping tube and to do so would practice the art disclosed herein—but that approach is estimated to be cost-ineffective at this time.

FIG. 18 Shows, in diagrammatic form, another embodiment with the Reflector's 37 shapes taken from the sides of a parabloloid and thus out of the shadow cast by the Band Pass Reflective Filter 41. In effect this is a contained, fractional version of the Cassigain variant sometimes attributed to Anton Kutter. The illustrated format optimizes the percentage of light ending at the exit for filtered light 74 and then, either the photovoltaic cell 38 or other uses and minimizes light to the less valuable heat service (elements of which are omitted for clarity.

It should be noted that one advantage of embodiments of the present disclosure is compatibility with building rooftops. Rooftop applications impose significant space and orientation limitations, yet they are very close to the loads they service and are often available for use. This proximity is vital to exploiting heat production in particular. Heat services (for example space and water heating) and heat serviceable loads (such as air conditioning and food refrigeration) are a significant fraction of a building's energy budget on a watt-hour basis as well as a money basis.

The form factor of the collector tubes 1 provides design flexibility in concentration ratios to suit a wide variety of photovoltaic cells 38. Employing small PV cells 38 (small relative to the parent wafers for instance) provides opportunities for economically specifying PV materials with greater efficiency and broader spectrum response. The inexpensiveness of the concentrating parts (for example glass and sheer deposits of metals) means that this form factor can support various yield-mixes of heat, electricity (and optionally light) depending on the PV materials chosen and the precision/design of the optics (reflectors and filters primarily.) The small size of the exit for filtered light 74, the two steps of concentration from the primary and secondary surfaces and the space available for a collimating/homogenizing tube 56 mean that in the form factor disclosed, the distribution and concentration level of the light upon and across the cell's 38 surface area is highly controllable. Photovoltaic cell efficiency optimizing strategies that have high costs per square cm (and so are prohibitively expensive for employment on flat panel collectors) may be economically applied in concentrators of the envisioned embodiment.

The tubes may be terminated with a drive hub that engages a tracking drive in the tube-drive and heat exchanger interface 112 (also termed a “header”). A computer controlled motor drives the tubes for the east west tracking of the sun. The computer, using the equation of time (with data tables on the interne or stored within) combined with location and orientation information about the particular installation, moves the array predictively rather than responding, for instance, to light sensors. Alternate embodiments could employ sun tracking sensors and drive the movement of the solar collector in response to the suns apparent movement.

The heat pipe condenser 16 may exit the top of the collector tube 1 through the drive hub and enter the heat exchanger 13 within the Tube-Drive and Heat Exchanger interface 112 (“header assembly”.) The header assembly may have a cold entry for coolant to flow past the hind rank (or plane) 8 of tubes' condensers 16 and a return along the foremost rank (or plane) 7 of tubes' condensers 16 back to the hot exit. During the non-peak hours when the foremost rank of tubes is significantly shading the second, hindmost rank, as in FIG. 3, the temperature difference between the coolant and the condensers is greater on average. As a result this “hind-to-fore” path, generates higher heat output.

The foremost rank (or plane) 7 of tubes and the hind rank of tubes 8 have differing exposures to the sun and through proportioning valves in place of the union for heat take-off 17 can be operated at the same desired temperature by tuning the proportioning valves dynamically in response to the temperatures of the two ranks.

The end of the collector tubes' 1 photovoltaic cell sub-assembly 12 is the exit of the DC wiring harness 72 from the wiring chase formed by the heat sink 43. The collector tubes 1 are joined into at least two separate electrical busses 35 in the header. The foremost 7 and hindmost 8 ranks of collector tubes 1 may be joined to separate busses 35 and separate inverters 79 as their shading schedule is, by design, different over the course of the day. Other, additional circuit separations are possible and may be desired to respond to site shading conditions for example. These are achieved in the field during installation by joining and/or cutting the electrical buss lines 35 in the header 112 in order to group collector tubes electrically.

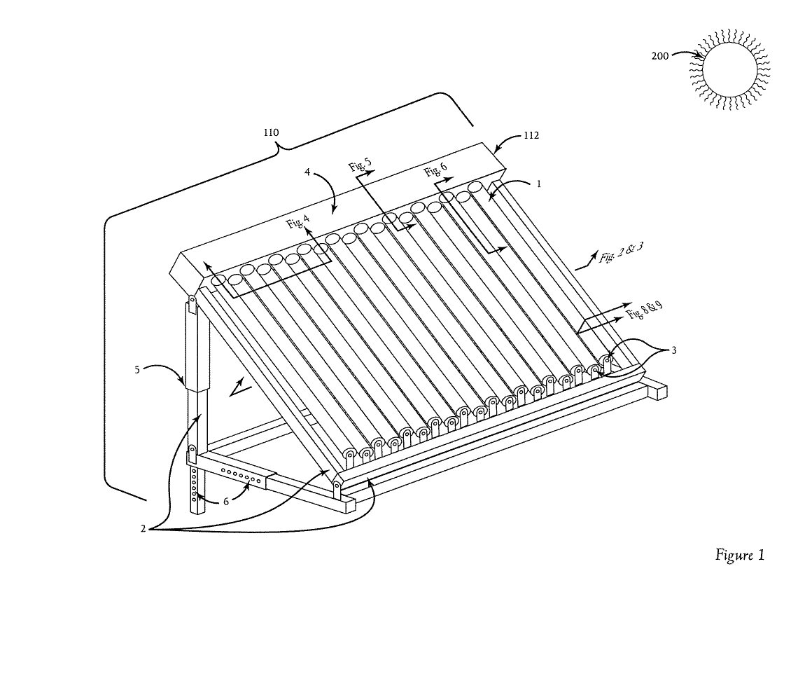

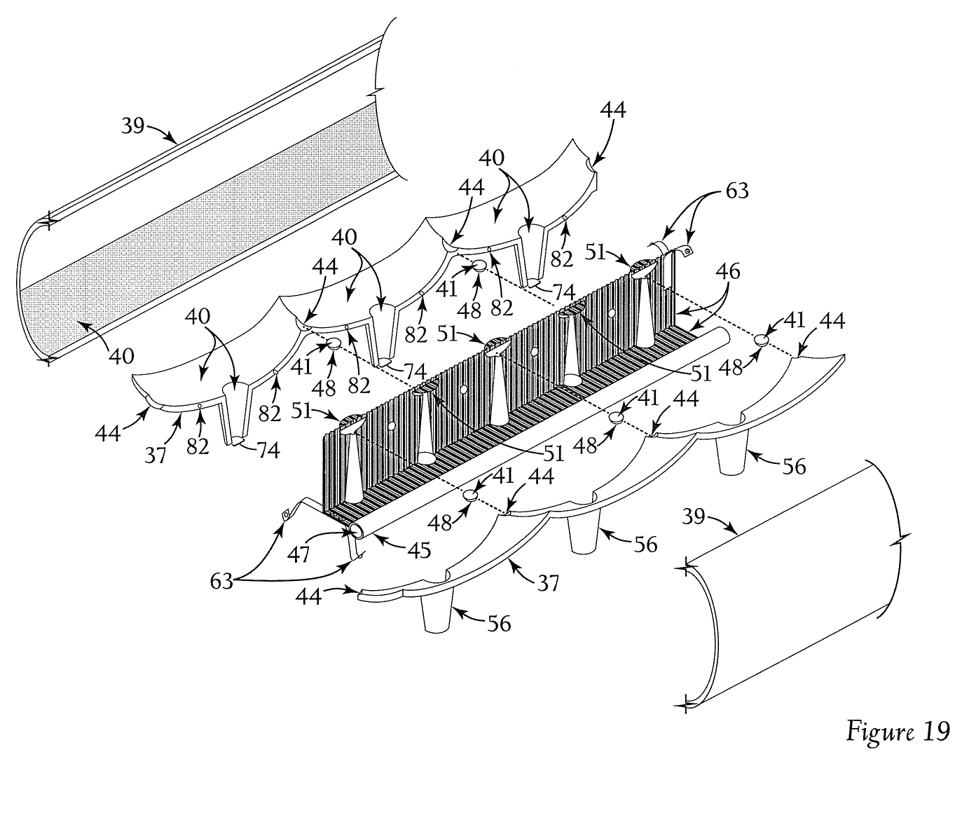

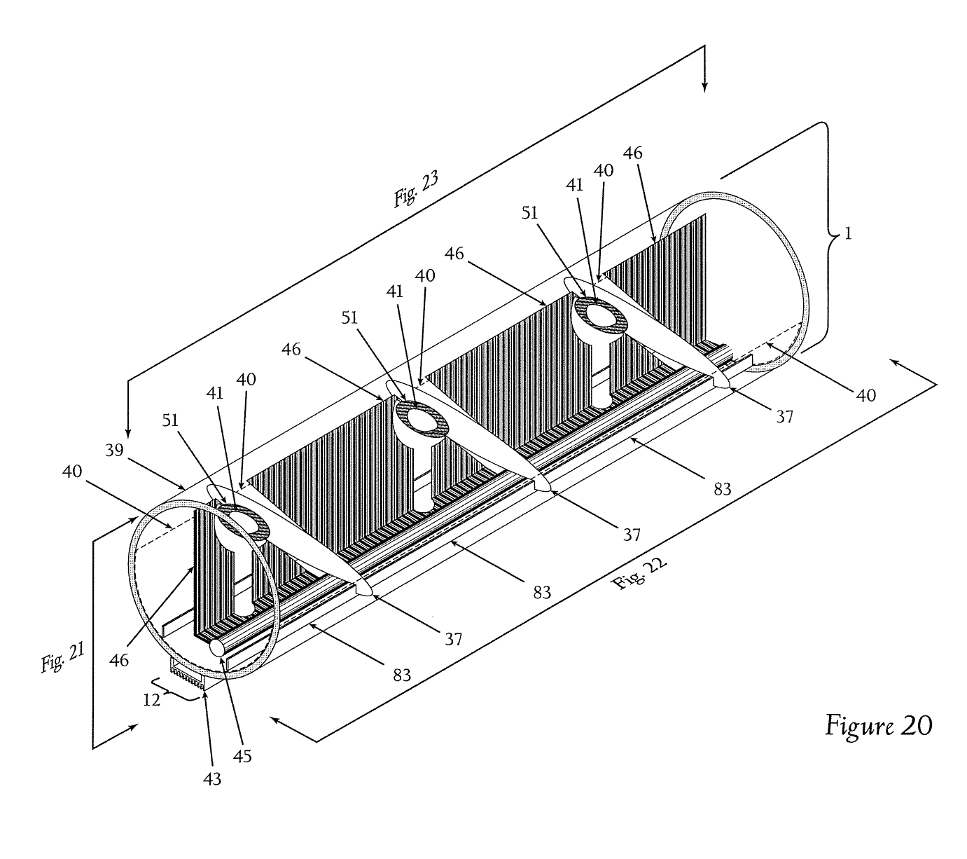

Referring to FIGS. 1-23, exemplary embodiments of hybrid thermal photovoltaic solar energy collection systems (“hybrid solar energy system” 110), apparatuses (“collector tubes” 1) and methods of construction 128 will be described. FIG. 1 illustrates an exemplary embodiment of a hybrid solar energy system 110 including a plurality of collector tubes 1 supported by a support assembly 2, including tube pivots 3 and a Tube-Drive and Heat Exchanger (“tube interface”) 112. The collector tubes 1 are, in one embodiment, evacuated tubes that include photovoltaic cells 38 and a heat pipe evaporators 45 within which a heat transfer medium 47 flows. The tube pivots 3 allow each collector tube 1 to rotate about its own axis. The tube interface 112 includes thermal collection (“heat collection”), a mechanism for rotating each collector tube 1 and a mechanism for managing the elevation of the tube-drive and heat exchanger 112 (a super set of the “Sun Tracking Device” and the heat capture), and one or more direct current (DC) electrical bus(es) 35.

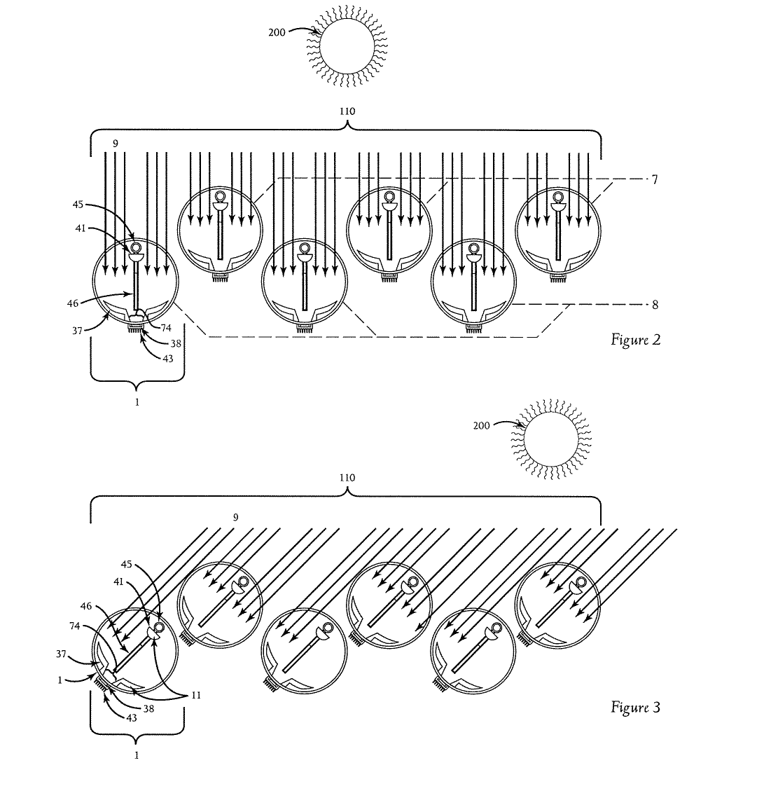

The solar energy system 110 is typically inclined to match the sun's elevation and held in proper aim by an azimuth adjustment 5. As described subsequently, the collector tubes 1 may contain optical elements 37, 40, 41, 44, 48, and 56 that concentrate incident sunlight within each tube. These perform better when the tubes are rotated about their axis to track the sun's progress throughout the day. The embodiment of FIG. 1 thus provides collector tubes 1 that are held in place by a tube interface 112 and tube pivots 3 to provide for both tilting the planes of tubes up and down to correspond to the seasonal changes in the elevation of the sun's path, and rotation to track the sun during the day (east/west.) More specifically by rotating each tube on its central axis as the day passes. At the end of the collection day or before the next collection day the tubes are counter-rotated to an eastward facing stance to ready them for the next day's collection. Likewise, the azimuth is adjusted between collection days in anticipation of the next day's solar path. As mentioned above, FIG. 1 shows a general arrangement of arrayed collector tubes 1, which are held in a pair of parallel planes 7 & 8 whose relationship in the transverse section is maintained by a tube interface 112 which is, in turn supported by a support structure 2 with pivots 3. This parallel plane configuration is further illustrated in FIG. 2.

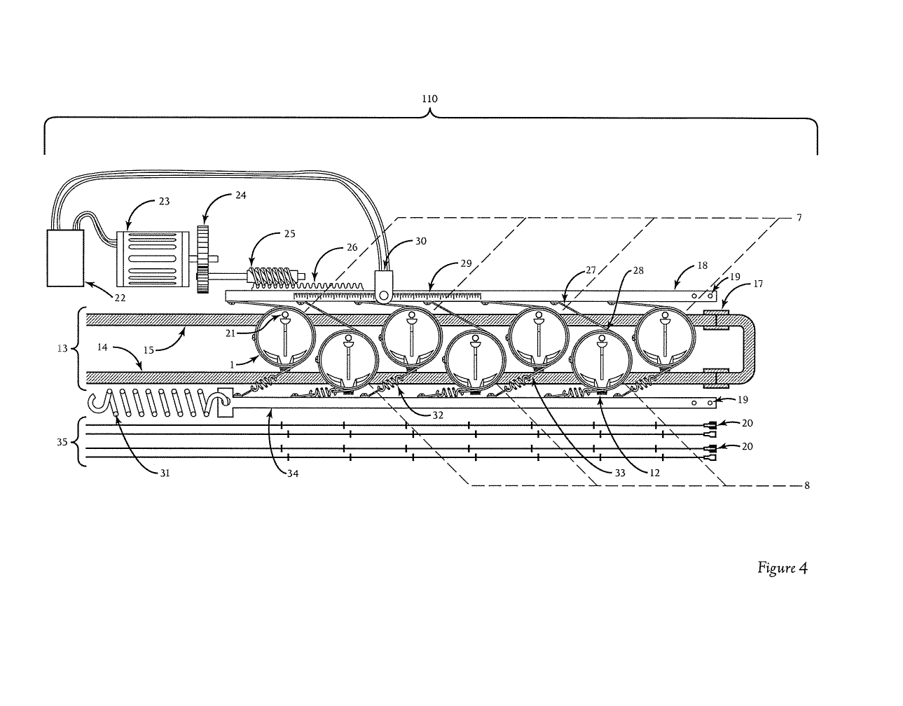

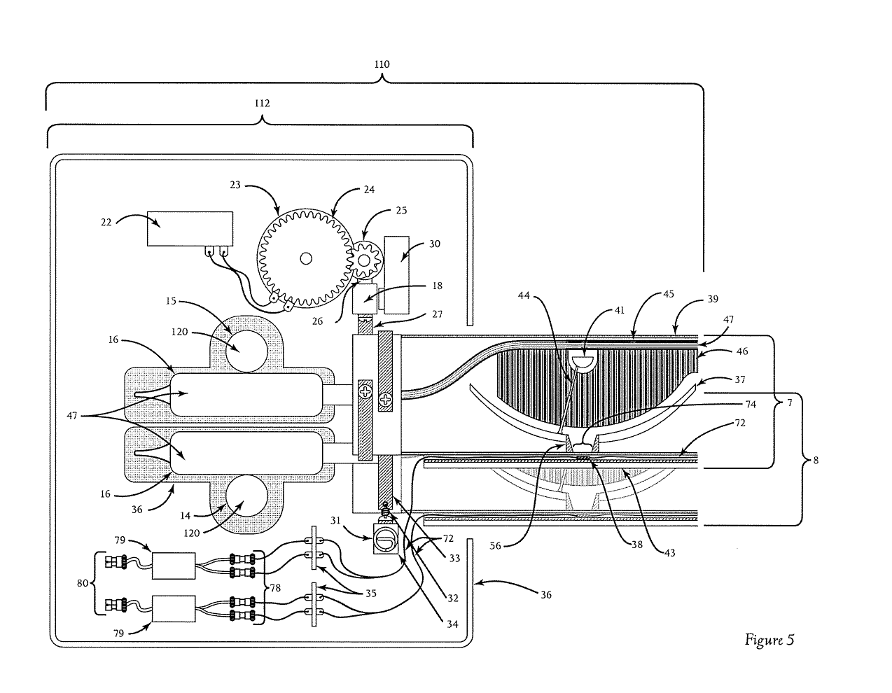

Tracking is accomplished in two axes, i.e., via two axes of control: by motorized articulation of the elevation adjustment legs 5 for the sun's apparent elevation in the north to south axis and by rotation of the collector tubes 1 about their long axes on the pivots 3 by a sun tracking east to west drive in the tube-drive and heat exchanger interface 112 which is illustrated in FIGS. 4 and 5. This tracking strategy is known to the art as “Tip and roll.”

Each hybrid solar energy device 110 includes a plurality of collector tubes 1 each composed of an enveloping tube 39 with an evacuated atmosphere 42 and made of broad spectrum transparent glass (borosilicate for example) within which are one or more heat pipe evaporators 45 and Cassegrain sub-units 11. Photovoltaic cells 38 are arrayed on the long dimension, held by a photovoltaic cell sub-assembly 12. These photovoltaic cell sub-assemblies 12 and the heat sink 43 that they occupy are attached to the side of the enveloping tube 39 opposite the sun. These elements together provide the electrical energy collection utility. These parts and their enmeshed arrangement are elaborated in FIGS. 6 through 16, 18-20.

Each collector tube 1 in a hybrid thermal photovoltaic solar energy collection system 110 of this design may be composed to produce, as separate energy service streams, a combination of: A) heat conveyed in a coolant, B) electricity as direct current (DC) or alternating current (AC), C) light filtered of infrared (IR) and ultra violet (UV) to the building associated beneath or near it or D) comprehensive shade. In the case of the electricity this service stream can be directed to the electrical grid, other means of electrical storage, or immediate use. In the case of heat, the service stream can be directed to storage, to use or dumped as heat exhaust. In the case of filtered light the service stream can be directed to skylights, light pipes or the like. In the case of comprehensive shade the service is limited to the surface covered by the solar energy system 110.

FIG. 1 shows an embodiment of a solar energy system 110 as it might sit on a horizontal surface such as a flat or minimally pitched roof. It is a feature of disclosed embodiments that the support structure 2 can be simply and broadly adapted to the location's requirements by changing the length of the elevation adjustment legs 5 with the addition or subtraction of installation leg extensions 6 or other mounting aids as are used in the solar panel installation industry.

FIGS. 2 and 3 are sectional views of 2&3-2&3 of FIG. 1, showing a cross sectional view through the collector tubes 1. The collector tubes 1 include optics (e.g., reflector device 37 and reflective filter 41) to concentrate sunlight and may be rotated about the tube axis to point at the sun 200. FIG. 2 illustrates the orientation of the collector tubes 1 when the sun 200 is at its highest point in the sky (“noon”) and FIG. 3 illustrates the orientation of the collector tubes 1 when the sun 200 is away from its highest point in the sky (“non-noon”). By rotating as illustrated the collector tubes 1 keep their optics aimed to catch the direct normal light 9.

The hybrid collector system employs glass tubes held in two parallel planes, indicated as 7 and 8 in FIG. 2 and FIG. 3, where plane 7 (the foremost rank of collector tubes) is closer to the sun than plane 8 (the hind most rank of collector tubes). Individual collector tubes 1 are positioned such that, when the sun is at the noon position, the each collector tube 1 in the foremost rank 7 captures a full exposure of the sun and the tubes in hindmost rank 8, fill in the gaps of the foremost rank's 7 coverage and additionally catch the edge reflections paths 207 and 304 (in FIGS. 8 and 9) from the collector tubes 1 of foremost rank 7. The collector tubes 1 are preferably arranged to permit air to circulate and permit installation and servicing individual collector tubes 1. The arrangement of collector tubes 1 in two ranks, maximizes the use of the available solar aperture for a given installation site. It also prevents “leakage” of sun through the collector to heat the roof of the building below where it would create a cooling load. The collector tubes 1 contain a maximally reflective layer 40 on a reflector 37 (shown in more detail in FIGS. 6, 7, 8, 9, 10 and 18-23, and also referred to herein, without limitation, as a primary element) as well as sections optionally of the interior wall of the enveloping tube 39. With this stacked arrangement or ranks, the device 110 may act as a comprehensively reflective silver roof for the building below—reducing, for that structure, the cooling demand at the peak of the air conditioning load period.

Each collector tube 1 includes an enveloping glass tube 39 that may have a circular cross-section that is substantially evacuated of gas, which encloses a heat pipe evaporator 45, and a photovoltaic cell 38, which could be inside or outside the tube 39. The heat pipe evaporators 45 receive, preemptively, the parts of the light spectrum incident on the collector tube 1 that are either not transformable by the photovoltaic device 38, or do not enter the optically concentrating paths, or are otherwise directed away from the exit for filtered light 74. This is accomplished by the positioning of the photovoltaic material in the predominant optic paths only after the band pass reflective filter 41. The photovoltaic cells 38 are also positioned at focal points that may lay in the shadow of both the heat pipe evaporator 45 and the light-spill capture cap 51. Due to the specificity of the light (now primarily composed of selected wavelengths 49) incident upon the photovoltaic cells 38, they can to operate at lower temperatures and thus generate more electricity. The heat pipe evaporator's 45 thermal output is also able to run at high temperatures without degrading the performance of the photovoltaic components 38. The details of an exemplary collector tube (or “solar energy apparatus”) 1 are shown in more detail in FIG. 6 as a sectional longitudinal sectional view 6-6 of FIG. 1, FIG. 7 as a lateral sectional view 7-7 of Figure. 6, and in part, by FIG. 14 as a longitudinal view of a heat pipe evaporator 45 and fin 46 and shows their roles in the heat circuit 21.

As described subsequently the arrangement of the Cassegrain subunits 11 provide for flexibility in configuring solar collector apparatuses 1 and Hybrid Solar Systems 110 to conform to the capabilities and resources of a manufacturer, and flexibility to meet a variety of customer energy production needs even within a single installation. Electricity, process heat, domestic hot water, air conditioning, food cooling, space heating, and heatless light are all extractable with the same device variously appointed.

The enveloping tubes 39 may be formed from glass that is highly transmissive of solar radiation. In exemplary embodiments, the solar energy apparatus 1 contain at least two energy collection facilities, one thermal (in the form of a heat pipe evaporator 45 contained within the inner surface of the enveloping tube 39) and the other including either photovoltaic cells and/or UV filtering light passages (or “UV light filters”) 81. Specifically, the solar energy apparatus 1 may include a plurality of Cassegrain subunits 11 having a reflector device 37 that, with a mount 44 to support a band pass reflective filter (a “low-pass” or “cold mirror” 41 in exemplary embodiments,) is mounted behind, from the sun's perspective, a heat pipe evaporator 45. The reflector device 37 focuses incident sunlight onto the band pass reflective filter 41 (also referred to herein, without limitation, as a “secondary element”). The heat target tube (evaporator) 45 is common to all Cassegrain Subunits 11 within a given collector tube 1.

A fraction of the solar energy passes through the band pass reflective filter 41 and is absorbed into the portion of the heat pipe evaporator 45 that is shaded from the direct normal sunlight 9. The heat pipe evaporator 45 transmits the separated heat energy (or deselected wavelengths 50) from each Cassegrain subunit 11 to the heat collection portion of the tube interface 112 via the heat pipe evaporator 45 to the heat condenser 16, where thermal heat is extracted by the hybrid solar system 110 using a heat exchanger 13 within the heat exchanger housing 36. The other selected wavelengths 49 of solar energy are reflected from the band pass reflective filter 41 onto the photovoltaic cell 38 below the Cassegrain subunit 11, where it is converted to electric current. Alternatively the photovoltaic cell's 38 position is occupied by a UV filter 81 for daylighting. Wires pass power between each photovoltaic cell 38. The DC current is conducted to the top end of the collector tube 1 to a DC electrical bus 35 in the tube interface 112.

The linear array of Cassegrain subunits 11 may be held in a single line parallel to the axis of the enveloping tube 39 to act as either a single trough, or as a series of wells (as in an egg carton split in half lengthwise.) In the case of the trough embodiment, the band pass reflective filter 41 may be a dual use of the surface of the bottom of the heat target tube (evaporator) 45. That surface may be treated with a band pass reflective filter coating 48 or material or have an underlying element treated with reflective filter material. In the alternate case of the row of shallow wells or bowls, the secondary is more like a row of lenses (potentially faceted) and each stands on a mast (or a “mount”) 44 in the illustrated embodiments, which is emerging from or affixed to the primary mirror (most likely within the shadow of the heat pipe evaporator 45.)

The heat pipe evaporator (or “heat target tube”) 45 may be coated with a broad-spectrum selective coating 76. The heat pipe evaporator 45 is also thermally bonded to the scatter fin 46, which may have a similar broad-spectrum selective coating that acts as comprehensive light collection element. As shown in FIG. 6, and with reference to FIGS. 7-10, the scatter fin 46 extends from the heat target tube (evaporator) 45 towards the reflector device 37, has a cut out for the band pass reflective filter 41, and is contoured to conform to the shape of the reflector device 37. The scatter fin 46 provides for both stiffness in the heat pipe evaporator 45 and for the collection of scattered light and the suppression of stray specular reflection to the ground of sky images or the like. The scatter fin 46 also allows the heat pipe evaporator 45 to be narrower in cross section east/west and so would allow more light to pass and hit the reflector device 37. Optionally, the heat target tube (evaporator) 45 and scatter fin 46 can be coated on the sides facing away from the sun with coatings that emphasize aesthetic performance rather than thermal performance.

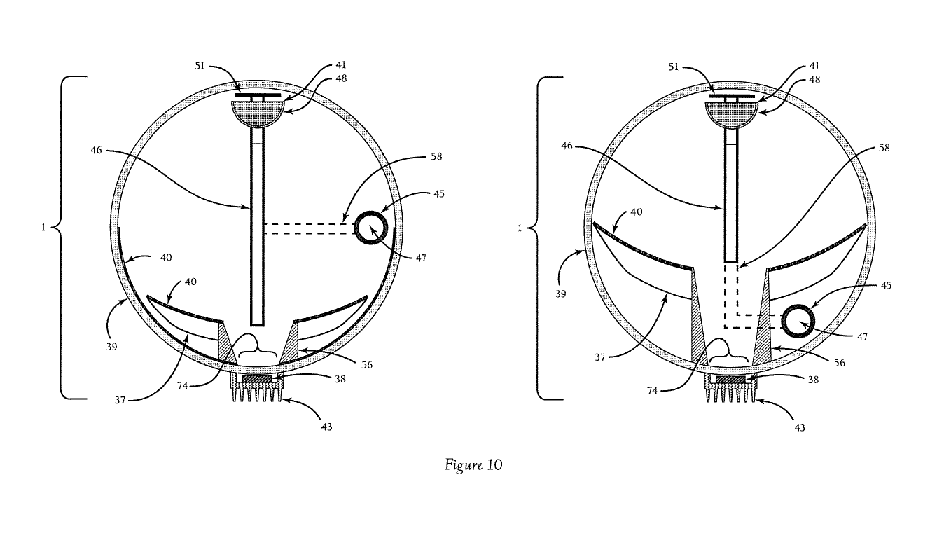

Alternately the scatter fin can extend upward from a heat pipe evaporator 45 located under the reflector 37. This still has the stiffening effect on the heat pipe evaporator 45 and has the additional advantage of greater flow of DNI 9 to the reflector 37 and thus more energy at the exit for filtered light 74. This up from beneath the reflector 37 format can be seen in FIGS. 10 (right most) 18, 19, 20 (21, 22.)

Each reflector device 37 can be made with varying degrees of precision depending on the intended price or performance point of the desired product. Parabolas are one ideal shape, but spherical sections and other non-parabolic sections can work well enough given the non-imaging aspect of the format. So their (the spherical section shapes) ease of manufacture can be exploited. The light reflected from the reflector devices 37 need only be approximately convergent at the diameter of the band pass reflective filter 41, which can be designed to “correct” the reflector's 37 light pattern as it redirects the light to the photovoltaic cell 38.

The exit for filtered light 74 (or “target area”) for the band pass reflective filter's 41 selected light 49 reflective paths 202 and 208 (as opposed especially to the transmissive paths, primarily 206) is either fitted with a photovoltaic cell 38, as shown, or alternatively, is fitted with a UV filter 41 which sits above a visible light target (outside and apart from the solar collection device 110) such as a light pipe array or a skylight, and may contain a diffuser or the like. In the thermal plus photovoltaic configuration, the photovoltaic cells 38 experience smaller heat and cool cycles and can, for the limited heat cycles they do face, “float” within the carrier 43 (in contrast to those vacuum pressed into a sandwich assembly as in a flat panel collector.) So photovoltaic cells with greater dimensional variance (like high aspect front side conductors) and greater delicacy (thinner, for instance) can more safely be employed. The various surfaces and coatings within the tubes are protected by a vacuum and so need no protections from weathering. Certain embodiments where the photovoltaic cells 38 are positioned within the enveloping tube 39 allow the photovoltaic cell to enjoy the protection of the vacuum and thus they do not need protective coatings either (and so can be spared the costs and losses inherent in those coatings.)

The concentration ratios and the small size of the photovoltaic cells 38 required also provide opportunities for economically upgrading the photovoltaic materials with others of greater efficiency and or higher concentration tolerance, and/or broader spectrum response. The inexpensiveness of the concentrating parts (glass and sheer deposits of reflective coatings) and the variety of concentrations available to the two-piece Cassegrain format, means that this form factor can support various ratios of heat and electricity yield depending on the photovoltaic materials chosen and the precision and the concentration ratio of the designed optical path. The small size of the target area and the two steps of magnification also mean that the distribution of the light across the target is controllable and there would be increased incentives to put the conductive grills and busses on the backside of the photovoltaic target or employ other relatively expensive cell optimizing strategies that are cost prohibitive on flat panel collectors.

The photovoltaic cell 38 can be mounted below the part of the primary reflector 37 that is farthest from the sun 200 (much as in a straight Cassegrain telescope.) As a result, a concentrating and homogenizing element (the collimating/homogenizing tube 56) can be optionally interposed to employ internal and/or wall reflections. This same homogenizing unit 56 can act as a heat sink for any remaining heat buildup in a photovoltaic cell by having a contact with the wall of the enveloping tube and bridging the heat out to the exterior.

The shadow of the heat pipe evaporator 45 on the reflector device 37 in the exemplary embodiment may be minimized by placing buss sections of the photovoltaic cell's 38 conductor mask/grill in that shadow. In absence of the grill (with backside conductors for example) the shadows of the heat pipe evaporator 45 and the mast holding up the secondary element 41 can be diffused by de-tuning the secondary reflector's surface and/or location and by use of an collimating tube/homogenizer 56, or exploiting the astigmatism imposed by the curvature of the enveloping tube 39 and other techniques developed in the discipline of optics, all with an eye toward even illumination of the active portion of the photovoltaic element 38.

The location and orientation of the photovoltaic cell 38 may also be made tunable for optimal output by rotating the cell on its center to try different positions before fixing it in place according to the optimization method described elsewhere. To facilitate the optimization, conductors on the photovoltaic cell 38 can exit at concentric tabs so the cell can be oriented at any rotational position and be able to contact the bus-wires on the photovoltaic cell subassembly 12 which may be a region of the heat sink 43.

In FIGS. 2 and 3 an exemplary approach to maximizing the collection of the sunlight while following the apparent movement of the sun in the sky from east to west is shown. The solar energy apparatuses 1 are shown here in transverse section as held in two parallel arrays of same: one, a front rank of tubes 7 and two, a second, hind rank of tubes 8 forming 2 parallel planes. The interdigitated aspect is for the purpose of intercepting the majority of incoming direct normal light 9 and incoming indirect light 10 (indirect is not illustrated here in FIGS. 2 and 3—see FIGS. 8 and 9). Meanwhile, to keep the Cassegrain sub-units 11 aligned with the apparent movement of the sun from east to west, the solar energy apparatuses 1 are rotated on their central (long) axes in unison by the sun tracking east west drive 112, which is elaborated in FIGS. 4 and 5.

FIG. 2 represents a fraction of an arbitrarily sized solar energy collection system's 110 array of solar energy apparatuses 1. Disclosed solar energy collection systems 110 are configured to provide flexibility in sizing in the east west dimension allowing the use of more or fewer solar energy apparatuses 1 (as desired) to make optimal use of available sunlit areas. Likewise, the relative positions and spaces between the solar energy apparatuses (or collector tubes) 1 represented are just one of the many still within the conception of the device disclosed here. Depending upon the desired performance and cost for a system and intended installation environment, the system can be designed to hold tubes closer together or further apart in both the sunward/earthward axis and/or the east west axis.

In FIG. 3 the solar energy apparatuses 1 are shown as arrayed by a solar energy collection device, in section, as in FIG. 2. In contrast to FIG. 2, FIG. 3 shows a time other than solar-noon. The incoming direct normal light 9 rays are met by the Cassegrain sub-units 11 with their concentrating geometry directed perpendicular to the incoming direct normal light 9.

The east-west movement of the sun 200 relative to the hybrid solar collector's 110 location and the effects of the atmosphere's lens on the apparent location of the sun are known to the art as “sun tracking” and can be calculated in the digital control 22 elaborated in the description of FIGS. 4 and 5.

FIG. 4 shows the mechanical logic and order (without scale and structural details) for both the sun tracking east west drive 112 and the heat exchanger 13 in a section view taken at 4-4 of FIG. 1. FIG. 4 also discloses a method of controlled rotation of the solar energy apparatuses (or collector tubes) 1. A loop of pipe is shown as a cold inlet 14 circulating to a hot outlet 15 which together drive a heat exchanger 13 which encloses the heat condensers 16 (neither are visible at this section but at FIG. 5: parts 13 and 16.) The heat exchanger's 13 inlet circulates coolant 120 first to the heat exchanger 13 cool inlet 14 serving the hindmost rank of tubes 8 and then via a coolant return loop 77 to the heat exchanger 13 segment above, serving the hotter, more sun-exposed foremost or front rank of tubes 7 and then to the hot outlet 15.

In exemplary embodiments, the sun tracking east west drive, is composed of a digital control 22 for a stepper motor 23 which, using gear reduction 24 and a worm gear 25, moves a drive bar 18. The drive bar's 18 linear motion is transformed into rotational movement by draw straps 27 connecting the drive bar 18 to the drive hub 28 of each collector tube in the array. Alternative embodiments might drive only the foremost rank of tubes 7 and leave the hindmost rank of tubes 8 stationary. Other embodiments might drive the front rank of tubes 7 and the hind rank of tubes 8 with similar but separate drive apparatus. Other embodiments of the drive scheme would disengage the hindmost rank of tubes 8 from rotation except for that fraction of the day when the hind tubes are irradiated by the sun sufficiently to justify the effort. Other embodiments may replace the hindmost rank with stationary collector tubes 1 with only thermal and cool roof capabilities.

The rotational accuracy is maintained by software obtaining array positional information from position detection markings 29 read by a position reader 30. Dampening, forward and return to start movements may be accomplished by reversing the stepper motor 23, (or in alternate embodiments engaging a reversing gear) and/or by a return main drive spring 31 pulling, in turn, return strap tensioners 32 and return straps 33. The digital control 22 is a computer programmed with the geographic location and position of the hybrid thermal photovoltaic solar energy collection system 110 as well as a clock or clock information receivers (such as global positioning satellite signals or central radio clock signals) and a computer program. The program employing algorithms known to the art, to determine the apparent position of the sun given the time and date. Based on the combination of the installation data and the time information the digital control 22 commands the stepper motor 23 and the elevation adjustment legs 5.

FIG. 4 also shows the expandability of the device 110 with regard to size. The pipes of the heat exchanger 13 enter and exit on the same end of the tube-drive and heat exchanger interface 112 to facilitate instillation by reducing the amount plumbing done in the field. Furthermore, to provide easy addition of (or expansion of) collector area, the hybrid thermal photovoltaic hybrid solar energy system 110 may be provided with unions for electrical buss 20, unions for heat take-off 17, unions for drive 19 and unions for return bar 34 at the ends of tube-drive and heat exchanger interface 112. By way of these unions, modular extensions composed of additional tube-drive and heat exchanger interface 112 units of similar or different capabilities can be attached to expand the collection area.

FIG. 5 shows the mechanical logic and order (without scale and structural affordances) of both the sun tracking east west drive 112 and the heat exchanger 13 in a section view, along with that of FIG. 4, to expose the method of rotation of the collector tubes 1 and the association between the heat condensers 16 at the ends of the solar energy apparatus 1 and the heat exchanger 13 which surrounds the heat condensers 16 and, by way of a circulating coolant 120 (such as water, water and glycol mixes, or other suitable materials,) extracts the heat collected by the collector tubes' 1 making it available for use. Heat energy within the heat pipe evaporator 45 transmits to the heat condenser 16 and, via phase-change, releases its energy to the coolant 120. Having conducted its heat to the coolant 120 in the heat exchanger 13, the heat pipe working media 47 in the heat pipe evaporator 45 is transformed by condensation into a liquid and falls down (or is wicked by suitable interior features of the heat pipe known to those conversant in the art) to the sun 200 exposed portion of the apparatus 1 to reheat and re-vaporize; repeating the cycle as long as there is sufficient sunlight energy incident on the solar energy apparatus 1.

In this embodiment the electrical buss(es) 35 for joining multiple collector tubes' 1 electrical products are within the tube-drive and heat exchanger interface 112 to share the protection of its housing and to facilitate quick installation. Each solar energy apparatus 1 has one or more electrical series strings 72 for the photovoltaic cells 38 and the terminal(s) for same can be joined to one or more electrical buss(es) 35 within the tube-drive and heat exchanger interface 112 according to an electrical plan determined to be optimal for the installation location and for the inverters 79 selected for the installation. Within the tube-drive and heat exchanger interface 112 are mounting points for low wattage inverters 79 (also known as “mini-inverters” or “micro-inverters.”) The electrical buss 35 is field configurable by selectively joining or severing the busses to join the collector tubes' 1 electric circuits of photovoltaic cells 38 in diverse combinations to address the installation's anticipated peak power production and the available type and size of inverter 79.

The heat exchanger housing 36 is thermally insulated from the environment by the tube-drive and heat exchanger interface 112 to reduce heat losses and is electrically grounded via the support structure 2. Also grounded by the support structure 2 is the tube-drive and heat exchanger interface.

The rotational accuracy of the solar energy apparatus' 1 movement is maintained by software obtaining positional information from position detection markings 29 read by a position reader 30. The movement management is described earlier for FIG. 4. In this embodiment of the hybrid thermal photovoltaic solar energy collection system 110 the electrical buss(es) 35 for the circuit of photovoltaic cell sub-assemblies are within the tube-drive and heat exchanger interface 112 to share the protection of the housing and facilitate quick installation. Alternate embodiments may house the electrical buss 35 elsewhere in the device. The hindmost rank 8 of collector tubes 1 is ghosted to distinguish the two ranks.

In FIGS. 6 and 7, an exemplary embodiment of a collector tube 1 is illustrated in cross-sections showing one Cassegrain sub-unit 11 and fragments of adjoining Cassegrain sub-units 11 to represent the repeating character of the collector tube 1 contents. Here the intertwined optical elements are seen in two views for clarity. The exemplary light paths provided by these surfaces are shown in FIGS. 8 and 9. For the length of the collector tube 1 there are Cassegrain sub-units 11 made up of a reflector 37 coated with a broad spectrum reflective coating 40 and a band pass reflective filter 41 which is composed to reflect wavelengths of light most compatible with the variety of photovoltaic cell 38 picked for employment. A UV filter for daylighting 81 is shown fitted in the exit for filtered light 74 in place of a photovoltaic cell 38 and the PV wiring harness 72 may bypass any UV filters.

Common to all the Cassegrain sub-units 11 in each collector tube 1 is a heat pipe evaporator 45 that runs the length of the collector tube 1. This heat pipe evaporator 45 is attached to, via a thermally conductive bonding method such as soldering or press-fitting, a scatter fin 46 of thin conductive metal, for example aluminum or copper, this scatter fin 46 is coated with a broad spectrum selective coating 76. The heat pipe evaporator 45 and the scatter fin 46 and a light-spill capture cap 51 along with a heat condenser 16 and standoffs 63 form the heat circuit 21 (isolated in FIG. 14) within the collector tube 1.

Convective and conductive losses from this heat circuit 21 are suppressed by an evacuated atmosphere 42 and the limited physical contact between it, as an assembly, and the rest of the collector tube 1. Conduction is limited to the standoffs 63, the collector drive hub's 28 contact point with the heat pipe evaporator 45 and, in the majority, to the heat condenser 16. The heat condenser 16 was shown in FIG. 5 with a surrounding heat exchanger 13, which is used to extract and move the high temperature heat energy away for work or storage.

As seen in FIG. 5 the topmost part of the collector tube 1 also presents DC lead ends of the PV wiring harness 72 from photovoltaic cells 38 of the solar collection apparatus 1. The collector tubes 1 are joined into at least two separate electrical busses 35 in the header. The foremost and hindmost planes of tubes may be connected to separate busses for separate inverters as their shading schedule is different over the course of the day. Other, additional, configuration and circuits are possible and may be desirable. These diverse circuit designs can be easily achieved by shorting and/or cutting the electrical bus lines in the header of the exemplary embodiment.

The entire hybrid solar collector 110, due to the requirement that it be aimed properly to generate voltage, is also able to turn itself off (or to be turned off) by any means that rotate the collector apparatuses 1 such that the primary reflectors 37 face the earth or substantially away from the disk of the sun. This provides an “off” or “safe” mode desirable to both installers and to the maintainers of the electrical grid or any who desire control over the array's production. It is likewise desirable for firefighting crews to safely de-power the system. Automatically initiating a battery or capacitor or even spring driven “turn down” for the tube array when the electrical grid fails is a simple matter and spares expensive DC arc suppression switches.

FIG. 10 illustrates exemplary alternative embodiments for the Cassegrain sub-units 11 with asymmetrical placements of the heat pipe evaporator 45 and different heights for the reflectors 37. In these exemplary embodiments the heat pipe evaporator 45 and scatter fin 46 are thermally linked by a lateral heat conduit 58 which may be a branch of heat pipe evaporator 45 or some other suitable thermally conductive link. This shifts the ratios of distribution of light energy for the Cassegrain sub-units 11 in favor of the electrical and/or lighting service by the increased passage of incoming direct normal light 9 to the reflector 37 and on to the band pass reflective filter 41 (paths 202 and 208) due to the placement of the heat pipe evaporator 45 either under the more steeply sloped areas of the enveloping tube 39 where reflection losses (like path 207 of FIG. 8) are greater, or in another alternative, entirely behind the reflector 37. In both cases the arrangement more thoroughly exposes (i.e. reduces shading on) the centerline of the reflector 37 (which enjoys the least lens effect from the enveloping tube 39 and the lowest reflective losses.) This comes at the cost of complexity of manufacture. The remaining components of these alternate embodiment examples are as described in FIGS. 6 and 7.

FIG. 11 shows various sections of a bottle preform 59 suitable for mass manufacturing using high-speed glass bottle production equipment. The concave indentations or bottle preform profiles 60 are starting points from which the reflectors 37 may be cut. In the disclosed exemplary embodiment the reflectors 37 are within the size capabilities of jug and some wine bottle production lines. In one production method, by first trimming out an oversized round first cut 62, the accuracy of the surface can be mapped such that optimal reflector trim lines 63 can be planned and cut (i.e. planning to omit the worst formed parts of the surface). Alternately the evaluation can happen before any cutting is done to the bottle preform 59. This topographic mapping and evaluation, including quality control checks, can be done before or after reflective coatings 40 are administered as the surface figure (or topology) is minimally altered by standard methods of applying a reflective coating 40.

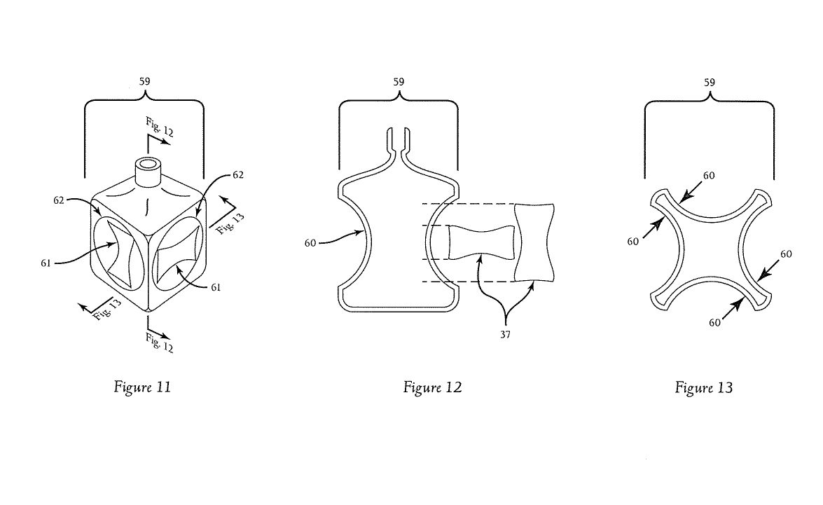

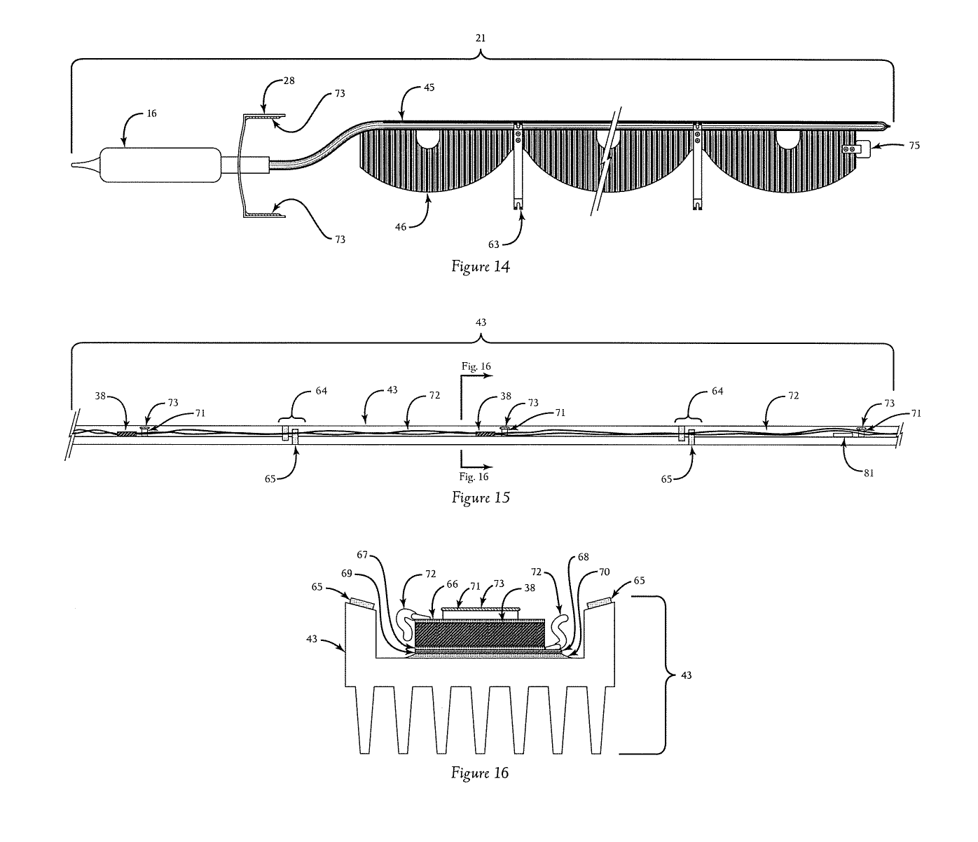

In FIG. 12 reflector trim lines 61 are shown projected from the bottle preform 59 at two of the many rotational points of orientation and at two different sizes to show that a variety of sizes may be cut from the same starting bottle preform 59 for first cut 62. FIG. 13 is a medial section of the bottle preform 59. In both FIGS. 12 and 13 the concave profile is the same, rotationally symmetrical, shape but need not be symmetrical on any particular axis and can be segmented paraboloids or any other shape suitable for the reflector 37 and compatible with the demands of high-speed bottle making equipment.

FIG. 14 shows an exemplary heat circuit 21 as an assembly separated from the collector tube 1 for clarity. An exemplary heat circuit 21 may be composed of a heat pipe evaporator 45, a scatter fin 46, a heat pipe condenser 16, standoffs 63 and a collection tube drive hub 28 and getters 75. This sub-assembly is held away from contact with the enveloping tube 39 (not pictured here) by the standoffs 63 and by seals with minimally thermally conductive character 73, bonds to the collection tube drive hub 28. Getters 75 support the vacuum. Getters, known to the art, scavenge stray gasses and vapors as they slowly liberate from the materials inside the collector tube 1 after sealing and during its service life. These getters 75 are attached to the scatter fin 46.

FIGS. 15 and 16 show an embodiment of the photovoltaic cell sub-assembly 12 composed of the heat sink 43 which fixes photovoltaic cell's 38 locations (or the UV filters 81 for daylighting) in the exit for filtered light 74 of the Cassegrain sub-unit 11 (not pictured here) beneath which it is to be affixed. This heat sink 43 is composed of segments bounded by expansion gaps 64 that are water proofed by sealing gaskets 65. Each photovoltaic cell 38 location within the photovoltaic cell sub-assembly 12 is adjustable in position for individual optimization at the time of assembly. Once optimized, the orientation is secured with thermally conductive metal filled adhesive 70 or the like.

The complete hybrid thermal photovoltaic solar energy collection system warms and cools over the daily work-cycle. To keep focus alignment between the Cassegrain sub-unit 11 and the photovoltaic cell 38 it serves, and to minimize the consequences of expansion and contraction, each photovoltaic cell sub-assembly 12 is bonded to the collector tube 1 at the heat sink bonding post 71 positioned in line with the exit for filtered light 74. Mechanical stresses produced by the differences in coefficient of expansion of parts 43 and 39 are thereby concentrated at, and absorbed by, the expansion gaps 64 and their sealing gasket's 65 flexibility.

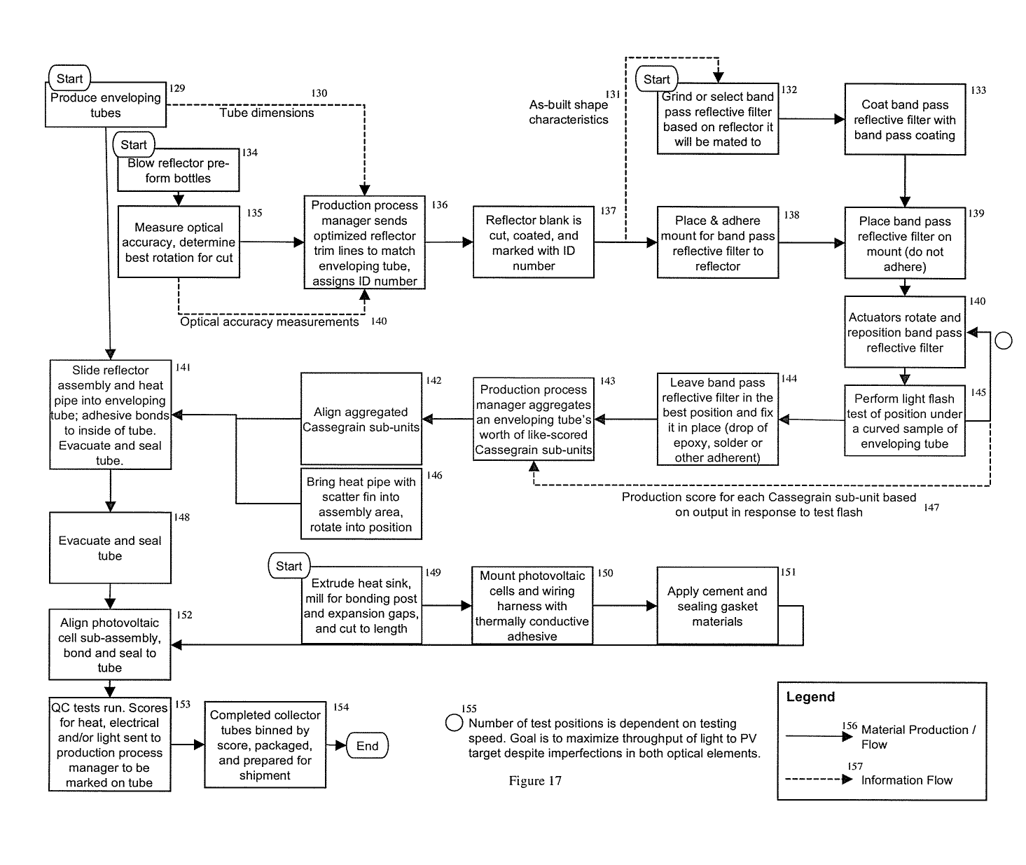

FIG. 17 represents the assembly logic for the solar energy apparatus 1. The goal being a collector tube 1 with similarly efficient Cassegrain sub-units 11 and photovoltaic cell sub-assembly 12 to minimize series circuit electrical losses (due to voltage mismatch) and to create sets of solar energy apparatuses (collector tubes) 1 matched by output. The current of the mismatched photovoltaic cells 38 is reduced to that of the least efficient Cassegrain sub-unit 11 and photovoltaic cell 38 pair in that series. This challenge is met by bin-sorting the Cassegrain sub-units 11 according to throughput as measured at the exit for filtered light 74, each enveloping tube 39 can be filled with Cassegrain sub-units 11 of close similarity in throughput. The resulting evacuated tube with Cassegrain sub-units 11 can then be characterized and mated with an appropriate group of photovoltaic cell sub-assemblies 12 and then bonded together according the to the mechanical scheme in the description of FIGS. 15 and 16 and become one collector tube 1 of the type here disclosed.

### Method of Manufacture:

Described below and flow charted in FIG. 17 are exemplary methods 128 for constructing the reflectors 37 and assembling them into groups for insertion into enveloping tubes 39 as well as a method for assembling and tuning the Cassegrain sub-units 11. This description is for illustrative purposes and is not meant to limit the scope of the present disclosure.

Step 129 is production of glass tubes. Step 130: in addition to working to a maximum and minimum wall thickness and inside and outside diameters as is conventional in glass tube production, an “as built” measurement is taken for each tube and sent for tracking to the production process manager 136.

Step 134 is the production of bottle performs 59. For illustrative purposes, FIG. 11 presents a perspective view of a general arrangement for pre-forming the reflectors 37 as bottles, FIG. 12 is a medial cross-sectional view of FIG. 11, and FIG. 13 is a transverse cross-sectional view of FIG. 11. By making the concave depression in the side of the bottle preform 59 large enough to provide the full range of mirror sizes, each mirror can then be cut out custom for each tube. Using conventional bottle making equipment the reflectors (or “primary mirrors”) 37 are formed at high speed and low-cost with inexpensive glass. As with usual bottle production, the preformed bottles are blown or inflated into forms. The bottle machines' forms surfaces are followed by the inflated glass gobs to create the “exterior shape” of the bottle. Bottle forms and inflation of glass gobs into them are an established highly automated craft. Imposing an inward depressions of a spherical or parabolic type allows for the repurposing or cross purposing of conventional bottle-making gear to provide the primary mirrors at high speed and low cost.

Step 135: completed bottle performs 59 have their surface accuracy measured and sent to Step 136 to determine the orientation for cutting a reflector with the over all best surface accuracy. The completed bottle perform 59 may be presented to a computer controlled water-jet cutter or suitable alternative in step 137 to be cut according to a plan composed by the production process management system step 136. The reflectors 37 are either coated while still attached to the bottle “blank” or after. The remainder of the bottle material (having served its armature purpose) is returned to the step 134 process as cullet (ground waste glass for reuse).

The reflectors 37 (or “primary mirrors”) are also given a specular finish via silver, aluminizing or dichroic coatings in step 137. As mentioned, in most cases the expense of protective layers can be omitted since the vacuum will protect them from tarnish and other degradation. The reflectors 37 are measured again and a prescription for a secondary band pass reflective filter 41 shape is formulated by step 132.

Step 132 (the start for the band pass filter 41 production), grinds or selects from prepared examples a candidate filter substrate and coats it as necessary with the band pass reflective coating 48 in step 133. In step 138 the reflector is fitted with a mount 44 for the secondary 41. Because this design employs many first surfaces (reflectors) it does not preclude the use of plastics, ceramics, or metals in the forming of the reflectors, mounts or filters. They need only tolerate/cooperate with the vacuum environment and the flux levels.

Step 139 unites (based on information from the 132 step about the prescription for the reflector 37) the reflector 37 with its filter 41. The filter 41 is serially repositioned in step 140, tested in step 145 for throughput at the exit for filtered light and then returned to step 140 iteratively until a predetermined number of positions have been tried per 155. The position with the highest throughput in step 141 is returned to by step 140 and then the reflector and secondary pair is sent to step 144 for securing.

Step 143 bin sorts the now mated and scored Cassegrain sub-units 11 into like scoring groups. When a quantity sufficient to fill an enveloping tube 39 is ready they are, in step 142 aligned. At the same time a heat circuit 21 has been prepared in step 146 (in the manner of known evacuated tube collectors but with the scatter fin 46 and heat pipe evaporator 45 shapes and asymmetries of the disclosed embodiment.)

The group of Cassegrain sub-units 11 gathered and aligned in steps 143 and 142 are united with a heat circuit 21 from step 146, adhesive 73 is applied to each Cassegrain sub-unit 11 and, in step 141 slid into an enveloping tube 39 of the size the Cassegrain subunits 11 for which they were custom-cut. Adhesive on 11 bonds to the inside of the enveloping tube 39. The collection tube drive hub 28 is adhered to the opening of the enveloping tube 39 and a vacuum is drawn and sealed in step 148.

Elsewhere, in step 149 a heat sink 43 is extruded, milled for bonding posts 71 and expansion gaps 64 and cut to length. Thus prepared, the heat sink goes to step 150 for the mounting of photovoltaic cells 38 and wiring harnesses 72 and optionally UV filters for daylighting 81 and thermally conductive adhesive.

Next in step 151 the outfitted heat sink 43 (now a photovoltaic cell subassembly 12) has cement and sealing gasket 65 materials applied and is sent to step 152. Step 152 joins the product of step 148 and aligns the photovoltaic cells 38 with the exits for filtered light 74 of the arrayed Cassegrain sub-units of the selected tube. Step 153 is QC testing and rating. Step 154 QC testing and rating data is used to bin, by score, the completed collector apparatuses 1 and box for shipment. Step item 155 clarifies the parameters by which the cycles are run between steps 140 and 145 as dependent on the desired speed of production. Step item 156 shows the continuous arrow representing material flow. Step item 157 shows the dotted line representing information flow.

A strong element of flexibility exists in step 132. The primary mirrors or reflectors may be, either on a batch basis or on an individual basis, tested for their focus quality and particulars and the secondary element (the band pass reflective filter 41) may be selected individually or ground to match. This can be likened to the process of providing eyeglasses for people. The primary is the person's eye and the secondary is the lens for the glasses. One can either pull glasses from an existing inventory (as the charity reuse of glasses programs do) or one can grind one custom (as an optometrist did for the original patient.) Both can work, depending on the available resources. In both cases one takes the eye (or reflector) as a given, and works to optimize around it (as it is more valuable/costly.)

More cost saving tactics are available to this production method. Pairs of primary 37 and secondary 41 filters that do not score even a minimally acceptable solar yield, are inexpensively sidetracked at this point for scrapping or non-photovoltaic hybrids such as heat shielded/heat-harvested skylights (which can generally tolerate less accurate optical performance) Or become part of discounted “heat only” tubes to aesthetically match other apparatuses in hybrid arrays. Each pair represents a small fraction of the production costs and can thus be economically recycled as a failed element before joining a larger assembly or redirected (as above to a “heat only” apparatus.)

Reference throughout this specification to “one embodiment” or “an embodiment” means that a particular feature, structure or characteristic described in connection with the embodiment is included in at least one embodiment. Thus, appearances of the phrases “in one embodiment” or “in an embodiment” in various places throughout this specification are not necessarily all referring to the same embodiment. Furthermore, the particular features, structures or characteristics may be combined in any suitable manner, as would be apparent to one of ordinary skill in the art from this disclosure, in one or more embodiments.

Similarly, it should be appreciated that in the above description of exemplary embodiments, various features are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed embodiments require more features than are expressly recited in each claim. Rather, as the following claims reflect, inventive aspects may lie in less than all features of a single foregoing disclosed embodiment.

It should be understood that any of the foregoing configurations and specialized components or may be interchangeably used with any of the apparatus or systems of the preceding embodiments. Although illustrative embodiments are described hereinabove, it will be evident to one skilled in the art that various changes and modifications may be made therein without departing from the scope of the disclosure. It is intended in the appended claims to cover all such changes and modifications that fall within the true spirit and scope of the disclosure.

I claim:

1. A solar energy apparatus, comprising:
at least one enveloping tube having an outer surface made of transmissive material and an evacuated internal atmosphere;
at least one heat pipe evaporator running longitudinally within the at least one enveloping tube;
at least one reflector device fixedly attached to an inner surface of the enveloping tube such that the reflector device is tilted relative to the normal axis of the enveloping tube;
at least one reflective filter located such that light meeting the reflector device is directed to the reflective filter; and
at least one photovoltaic device located such that at least a first portion of the light filtered by the reflective filter is directed to the photovoltaic device;
wherein a second portion of the light is transformed to sensible heat by and conducted through the heat pipe.

2. The solar energy apparatus of claim 1 wherein the reflector device is tilted at an angle of about 38-39°.

3. The solar energy apparatus of claim 2 wherein the reflector device is tilted such that a focal point and vertex is at least 38° 26′ 21″.

4. The solar energy apparatus of claim 1 further comprising at least one scatter fin fixedly attached to the at least one heat pipe.

5. The solar energy apparatus of claim 1 further comprising a reflective coating on the at least one reflector device.

6. The solar energy apparatus of claim 1 wherein the light entering the enveloping tube is broken into a plurality of paths, the light including direct normal light and indirect light;
wherein the direct normal light and the indirect light are concentrated at different ratios.

7. The solar energy apparatus of claim 1 wherein the first portion of light comprises direct normal light.

8. The solar energy apparatus of claim 1 wherein the second portion of light comprises direct normal light and indirect light incident upon the heat pipe.

9. The solar energy apparatus of claim 1 further comprising a third portion of light including indirect and direct light reflecting off the reflector device to a scatter fin such that the indirect light is absorbed by the heat pipe or exits the enveloping tube.

10. A hybrid solar energy system comprising:
a plurality of solar energy apparatus, each apparatus having:
an enveloping tube including an outer surface made of transmissive material and an evacuated internal atmosphere;
at least one heat pipe evaporator running longitudinally within the at least one enveloping tube;
at least one reflector device fixedly attached to an inner surface of the enveloping tube such that the reflector device is tilted relative to the normal axis of the enveloping tube;
at least one reflective filter located such that light reflecting off the reflector device is directed to the reflective filter; and
at least one photovoltaic device located such that at least a first portion of the light filtered through the reflective filter is directed to the photovoltaic device;
wherein a second portion of the light is transformed to sensible heat and conducted through the heat pipe; and
a support assembly holding the plurality of solar energy apparatus.

11. The solar energy system of claim 10 further comprising a heat exchanger housing connected to the support assembly.

12. The solar energy system of claim 11 further comprising a tracking drive connected to the support assembly.

13. The solar energy system of claim 10 wherein the reflector device is tilted such that a focal point and vertex is at least 38° 26′ 21″.

14. The solar energy system of claim 10 wherein the support assembly holds the plurality of solar energy apparatus in at least two substantially parallel ranks such that the apparatus held in a second rank substantially block gaps between the apparatus of a first rank and intercept surface reflections from the apparatus of the first rank.

15. A method of generating solar thermal energy and solar photovoltaic energy, comprising:
providing at least one enveloping tube having an outer surface made of transmissive material and an evacuated internal atmosphere;
fixedly attaching at least one reflector device to an inner surface of the enveloping tube such that the reflector device is tilted relative to the normal axis of the enveloping tube;
configuring at least one reflective filter such that light reflecting off the reflector device is directed to the reflective filter; and
configuring at least one photovoltaic device such that at least a first portion of the light filtered through the reflective filter is directed to the photovoltaic device;
configuring at least one heat pipe evaporator such that it runs longitudinally within the at least one enveloping tube and such that a second portion of the light is transformed to sensible heat and conducted through the heat pipe.

16. The method of claim 15 further comprising fixedly attaching at least one scatter fin to the at least one heat pipe.

17. The method of claim 15 further comprising directing the light entering the enveloping tube such that the light is broken into a plurality of paths, the light including direct normal light and indirect light and concentrating the direct normal light and the indirect light at different ratios.

18. The method of claim 15 wherein the first portion of light comprises direct normal light.

19. The method of claim 18 wherein the second portion of light comprises direct normal light and indirect light incident upon the heat pipe.

20. The method of claim 19 further comprising a third portion of light including indirect light reflected off the reflector device to a scatter fin such that the indirect light enters the heat pipe or exits the enveloping tube.

21. The method of claim 15 further comprising mis-tracking the sun to allow for off and heat only tracking patterns.

22. A solar energy apparatus, comprising:
at least one enveloping tube having an outer surface made of transmissive material and an evacuated internal atmosphere;
at least one heat pipe evaporator running longitudinally within the at least one enveloping tube;
at least one reflector device fixedly attached to an inner surface of the enveloping tube such that the reflector device is tilted relative to the normal axis of the enveloping tube;
at least one reflective filter located such that light reflecting off the reflector device is directed to the reflective filter; and
at least one location within the enveloping where a photovoltaic device or a UV filter may be located such that at least a first portion of the light filtered through the reflective filter is directed to the photovoltaic device or through the UV filter;
wherein a second portion of the light is transformed to sensible heat and conducted through the heat pipe.

23. The system of claim 10 wherein the supporting assembly maintains a front rank and a hind rank of solar energy apparatus such that a substantial majority of light is prevented from passing;
wherein a first portion of the majority of light is employed for lighting or electrical generation via photovoltaic transformation, a second portion of the majority of light is transformed to sensible heat and conducted through the heat pipe, and a third portion of the majority of light including indirect and direct light reflects off the reflector device to a scatter fin such that the indirect light is absorbed by the heat pipe or exits the enveloping tube.
